(19) United States
(12) Patent Application Publication
(10) Pub. No.: US 2026/0101576 A1
(43) Pub. Date: Apr. 9, 2026

(54) SEMICONDUCTOR DEVICE AND METHODS OF FORMING THE SAME

(71) Applicant: TAIWAN SEMICONDUCTOR MANUFACTURING COMPANY, LTD., Hsinchu (TW)

(72) Inventors: Tsung-Han CHUANG, Tainan (TW); Chia-Cheng TSAI, Hsinchu (TW); Jung-Hung CHANG, Changhua (TW); Hou-Yu CHEN, Hsinchu (TW); Yu-Xuan HUANG, Hsinchu (TW); Kuo-Cheng CHIANG, Hsinchu (TW); Chih-Hao WANG, Hsinchu (TW)

(21) Appl. No.: 19/040,914

(22) Filed: Jan. 30, 2025

Related U.S. Application Data
(60) Provisional application No. 63/703,968, filed on Oct. 6, 2024.

(51) Int. Cl. H10D 84/83; H10D 30/00; H10D 30/01; H10D 30/43; H10D 62/10; H10D 62/13; H10D 62/834; H10D 84/01

(52) U.S. Cl. CPC H10D 84/832; H10D 30/014; H10D 30/0191; H10D 30/43; H10D 30/502; H10D 62/121; H10D 62/151; H10D 62/834; H10D 84/013

(57) ABSTRACT

Embodiments provided are a semiconductor device, including a first device. The first device includes a first protrusion protruding over a substrate; a first nanostructure including a first semiconductor material and disposed over the first protrusion; a first epitaxial extension region disposed on a first sidewall of the first nanostructure; a first gate structure including a first lower portion between the first nanostructure and the first protrusion; a first insulating spacer disposed on a second sidewall of the first lower portion of the first gate structure; and a first source/drain region disposed adjacent to the first protrusion and the first sidewall of the first nanostructure. The first source/drain region includes a first continuous semiconductor layer disposed on side surfaces of the first epitaxial extension region and the first insulating spacer. The first continuous semiconductor layer has a higher concentration of the second semiconductor material than the first epitaxial extension region.

### CROSS-REFERENCE TO RELATED APPLICATIONS

This application claims priority to U.S. Provisional Application Ser. No. 63/703,968 filed on Oct. 6, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 6 are perspective views of intermediate stages of manufacturing a semiconductor device, in accordance with some embodiments.

FIGS. 7A to 21E are cross-sectional views of intermediate stages of manufacturing the semiconductor device, in accordance with some embodiments.

FIGS. 22A to 25B are cross-sectional views of intermediate stages of manufacturing the semiconductor device, in accordance with some embodiments.

FIGS. 26A and 26B are cross-sectional views of intermediate stages of manufacturing the semiconductor device, in accordance with some embodiments.

FIGS. 27A to 29B are cross-sectional views of intermediate stages of manufacturing the semiconductor device, in accordance with some embodiments.

FIG. 30 is a plan view of an intermediate stage of a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a semiconductor device and methods for manufacturing it. The method includes forming alternately stacked first and second nanostructures and replacing the second nanostructures with insulating nanostructures. The first nanostructures may have a high etch selectivity with the insulating nanostructures. Accordingly, epitaxial source/drain extension regions may be formed in openings formed by laterally recessing the first nanostructures without substantially damaging the predetermined gate structural profiles, which may be defined by the structural profiles of the insulating nanostructures. The epitaxial source/drain extension regions may include a semiconductor material (e.g., germanium) different form the semiconductor material (e.g., silicon) of the first nanostructures and thus can provide better electrical conductivity and abrupt dopant profiles junctions.

While the embodiments of this disclosure are discussed with respect to nanostructure channel FETs, such as Lateral Gate All Around (HGAA) FETs, Vertical Gate All Around (VGAA) FETs, Forksheet FETs, implementations of some aspects of the present disclosure may be used in other processes and/or in other devices, such as FinFETs, planar FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning, or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

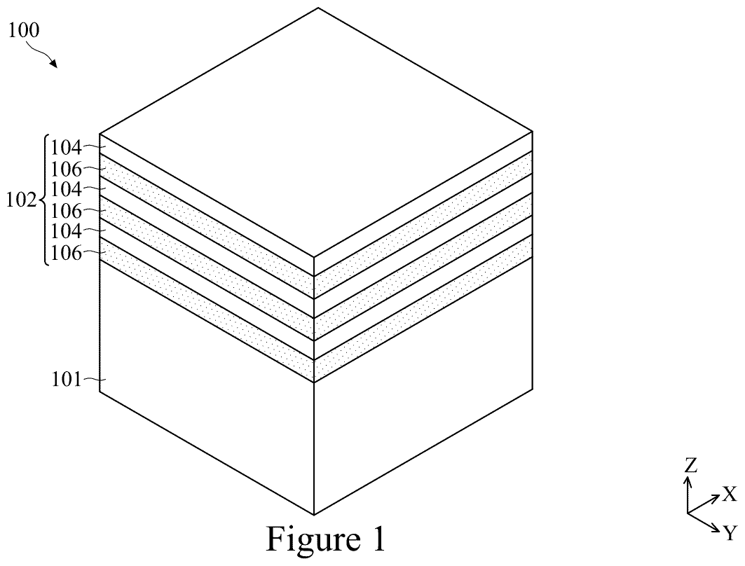

FIGS. 1-21E show exemplary processes for manufacturing a semiconductor device 100 according to embodiments of the present disclosure. It is understood that additional operations can be provided before, during, and after processes shown by FIGS. 1-21E, and some of the operations described below can be replaced or eliminated, for additional embodiments of the method. The order of the operations/processes is not limiting and may be interchangeable.

FIGS. 1-6 are perspective views of intermediate stages in manufacturing a semiconductor device 100, in accordance with some embodiments. The semiconductor device 100 also includes a multilayer stack 102 formed over the substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer. The substrate 101 may include various regions that have been doped with impurities (e.g., dopants having p-type or n-type conductivity) in the substrate 101.

The multilayer stack 102 includes alternating semiconductor layers made of different materials to facilitate the formation of nanostructure channels in a multi-gate device, such as nanostructure channel FETs. In some embodiments, the multilayer stack 102 includes first semiconductor layers 104 and second semiconductor layers 106 that are alternately stacked over the substrate 101. For example, the multilayer stack 102 is illustrated as including three layers of first semiconductor layers 104 and three layers of second semiconductor layers 106 for illustrative purposes. It is appreciated that any number of the first and second semiconductor layers 104, 106 can be included in the multilayer stack 102. In some embodiments, the first semiconductor layers 104 are formed of a first semiconductor material, and the second semiconductor layers 106 are formed of a second semiconductor material different from the first semiconductor material. The second semiconductor material may have a different etch selectively and/or oxidation rate than the first semiconductor material. In some embodiments, either the first semiconductor material or the second semiconductor material is or includes a material such as SiGe, SiC, GeAs, GaP, InP, InAs, InSb, GaAsP, AlInAs, AlGaAs, InGaAs, GaInP, GaInAsP, combinations thereof, or the like. In some embodiments, the first semiconductor material is formed of Si, and the second semiconductor material is formed of SiGe, or vice versa.

Each first semiconductor layer 104 may have a thickness in a range between about 4 nm and about 30 nm. Each second semiconductor layer 106 may have a thickness that is equal, less, or greater than the thickness of the first semiconductor layer 104. In some embodiments, each second semiconductor layer 106 has a thickness in a range between about 2 nm and about 50 nm. The first and second semiconductor layers 104, 106 are formed by any suitable deposition process, such as epitaxy deposition. By way of example, the epitaxial deposition of the multilayer stack 102 may be performed by vapor-phase epitaxy (VPE), molecular beam epitaxy (MBE), chemical vapor deposition (CVD), low-pressure metalorganic chemical vapor deposition (MOCVD) process, atomic layer deposition (ALD), the like, and/or other suitable epitaxial growth processes.

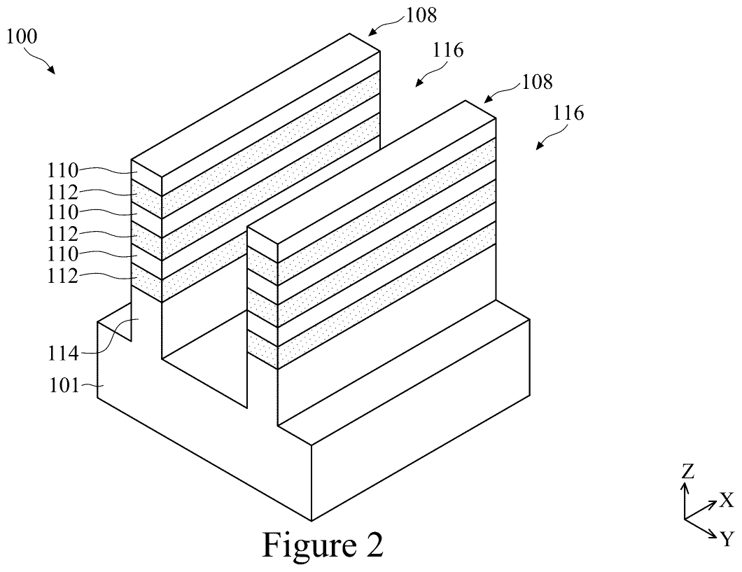

In FIG. 2, the multilayer stack 102 and the substrate 101 are patterned by one or more etch processes to form semiconductor strips 108, in accordance with some embodiments. Each semiconductor strip 108 may include first nanostructures 110 patterned from the first semiconductor layers 104 and second nanostructures 112 patterned from the second semiconductor layers 106. The substrate 101 may include a plurality of fins 114 after the etch processes. The semiconductor strips 108 are disposed over the fins 114, respectively. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section.

The semiconductor strips 108 may be formed by patterning a hard mask layer (not shown) formed on the multilayer stack 102 using multi-patterning operations that include lithography and etch processes. The etch process can include dry etching such as reactive ion etching (RIE) or neutral beam etching (NBE), wet etching, and/or other suitable processes. The lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etch process forms trenches 116 in unprotected regions through the hard mask layer, through the multilayer stack 102, and into the substrate 101, thereby leaving the semiconductor strips 108 and the fins 114. The trenches 116 extend along the X direction. In some embodiments, the semiconductor strips 108 and the fins 114 have a longitudinal axis along the X direction.

The semiconductor device 100 may include a plurality of transistor structures. The first nanostructures 110 or portions thereof may form nanostructure channel(s) of the transistor structures in later fabrication stages, while the second nanostructures 112 may act as sacrificial layers in later fabrication stages for allowing the nanostructure channel(s) to be surrounded by gate structures. The transistor structures having the nanostructure channel(s) may be referred to as nanostructure transistors, nanosheet transistors, nanowire transistors, gate-all-around (GAA) transistors, multi-bridge channel (MBC) transistors, or any transistors having gate electrodes surrounding channels.

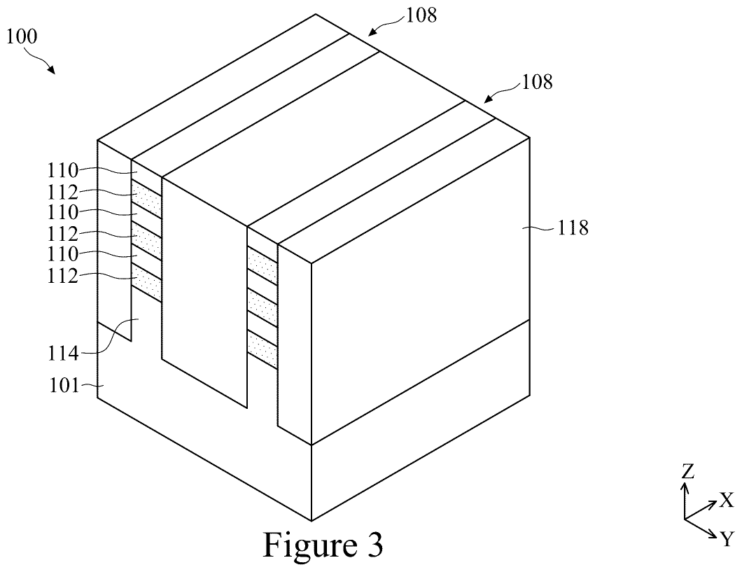

In FIG. 3, after the semiconductor strips 108 are formed, an insulating material 118 is formed over the substrate 101, in accordance with some embodiments. The insulating material 118 fills the trenches 116 between neighboring semiconductor strips 108 until the semiconductor strips 108 are embedded in the insulating material 118. Then, a planarization operation, such as a chemical mechanical polishing (CMP) method and/or an etch-back method, is performed such that the top of the semiconductor strips 108 is exposed. The insulating material 118 may be made of silicon oxide, silicon nitride, silicon oxynitride (SiON), silicon oxycarbonitride (SiOCN), silicon carbonitride (SiCN), fluorine-doped silicate glass (FSG), a low-K dielectric material (dielectric constant less than about 3.5), or any suitable dielectric material. The insulating material 118 may be formed by any suitable method, such as flowable CVD (FCVD), low-pressure chemical vapor deposition (LPCVD), or plasma-enhanced CVD (PECVD).

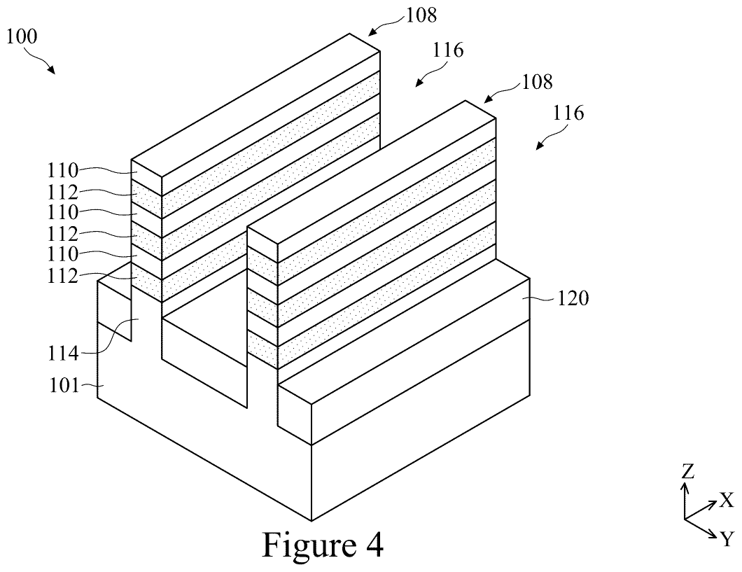

In FIG. 4, the insulating material 118 is recessed to form shallow trench isolation (STI) regions 120, in accordance with some embodiments. The recess of the insulating material 118 exposes portions of the semiconductor strips 108 and the substrate 101. The recess of the insulating material 118 reveals the trenches 116 between the neighboring semiconductor strips 108. The STI regions 120 may be formed using a suitable process, such as a dry etch process, a wet etch process, or a combination thereof. Top surfaces of the STI regions 120 may be level with or below top surfaces of the fins 114 and in contact with the fins 114.

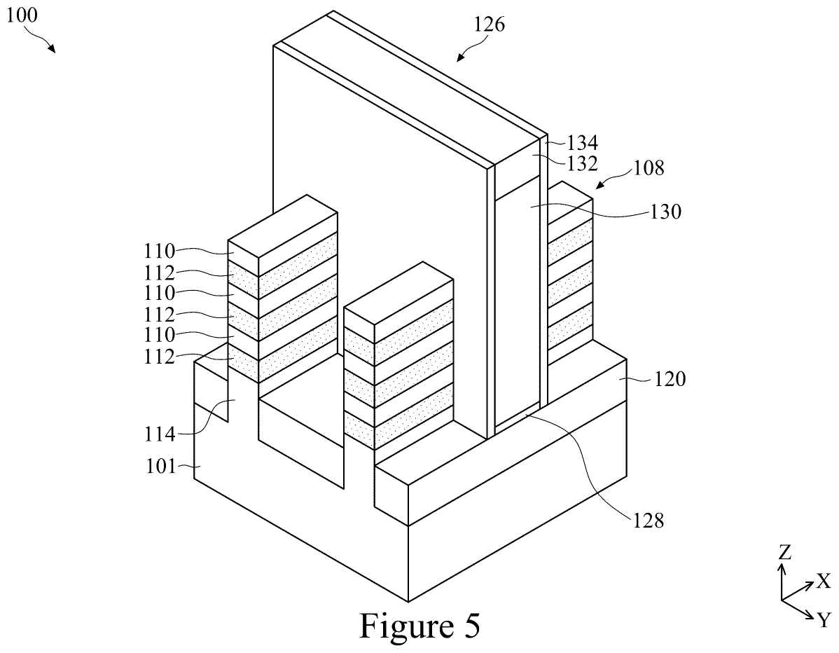

In FIG. 5, one or more dummy gate structures 126 (only one is shown) are formed over the semiconductor device 100. The dummy gate structures 126 are formed over a portion of the semiconductor strips 108. Each dummy gate structure 126 may include a dummy gate dielectric 128, a dummy gate electrode 130, and a hard mask 132. The dummy gate dielectric 128, the dummy gate electrode 130, and the hard mask 132 may be formed by sequentially depositing blanket layers of the dummy gate dielectric 128, the dummy gate electrode 130, and the hard mask 132, and then patterning those layers into the dummy gate structures 126. The dummy gate structure 126 may have a longitudinal direction (e.g., the Y-direction in FIG. 5) substantially perpendicular to the longitudinal directions of the semiconductor strips 108 (e.g., the X-direction in FIG. 5). The dummy gate structure 126 may land on the STI regions 120 and cross over a single one or a plurality of the semiconductor strips 108.

The dummy gate dielectric 128 may include one or more layers of dielectric material, such as a deposited oxide-based material (e.g., silicon oxide) or a material oxidized from the substrate 101. The dummy gate electrode 130 may include silicon such as polycrystalline silicon or amorphous silicon. The hard mask 132 may include one or more dielectric layers. For example, the hard mask 132 may be a combination of an oxide layer and a nitride layer.

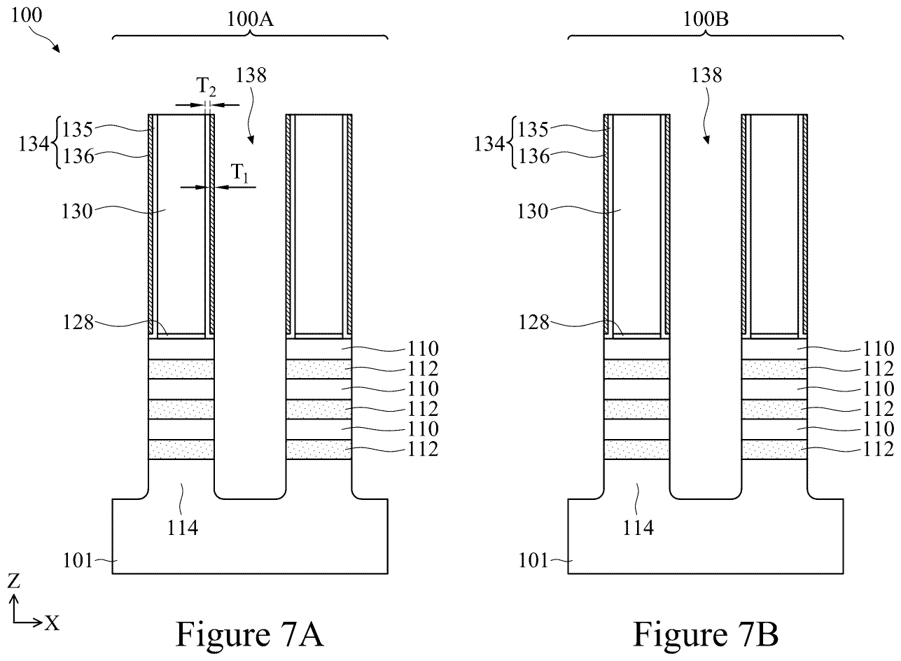

Gate spacers 134 are formed on sidewalls of the dummy gate structures 126. The gate spacers 134 may include a first gate spacer 135 and second gate spacer 136 as illustrated in FIGS. 7A and 7B, although more layers of the gate spacers can be implemented. In some embodiments, the first gate spacer 135 has an L shape, and second gate spacer 136 has an I shape over the first gate spacer 135. Alternatively, the first gate spacer 135 and the second gate spacer 136 may have different shapes or combination of same or different shapes, for example, both having the I-shape or a J-shape, or one having the I-shape with another one having the J-shape. Each of the first gate spacers 135 and the second gate spacers 136 may be formed by depositing a conformal layer and then anisotropically etching the conformal layer. The first and second gate spacers 135, 136 may independently be or include a dielectric material such as silicon oxide, silicon nitride, silicon carbide, silicon carbonitride, silicon oxycarbide, silicon oxycarbonitride, other suitable materials, or a combination thereof. In some embodiments, the first gate spacer 135 has a thickness T₁ ranging from about 2 nm to about 10 nm, and the second gate spacer 136 has a second thickness T₂ ranging from about 2 nm to about 10 nm.

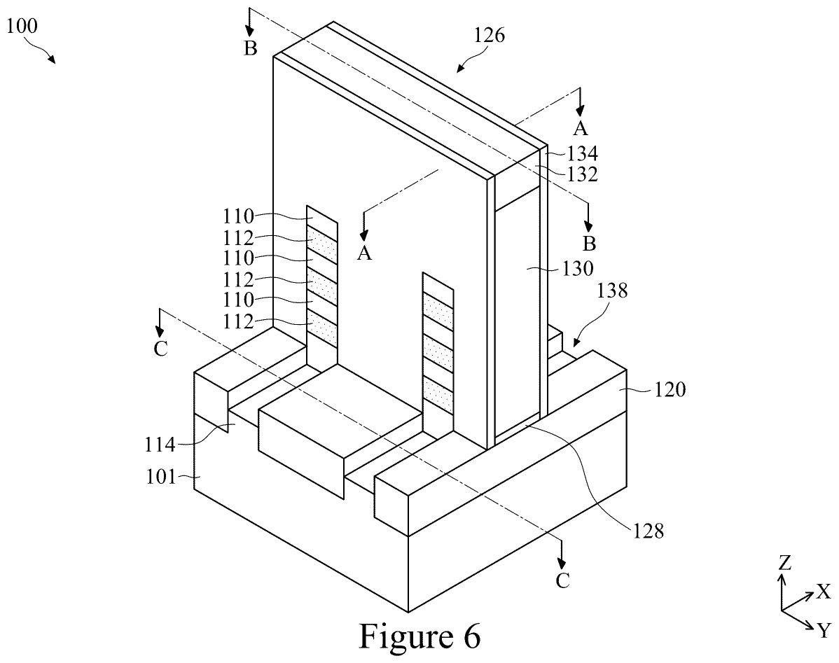

In FIG. 6, first openings 138 are formed in the semiconductor strips 108, the fins 114, and the substrate 101, in accordance with some embodiments. The first openings 138 may be formed by removing at least portions of the semiconductor strips 108 and the substrate 101 that are not protected by the gate spacers 134 and the dummy gate structures 126. As such, the first openings 138 may be formed between neighboring dummy gate structures 126 in the X-direction as illustrated in FIG. 6 (or the cross-sectional view illustrated in FIG. 7A). The first openings 138 may be recessed to below the top surfaces of the STI regions 120, although the first openings also can be recessed to level with or above the top surfaces of the STI regions 120. The first openings 138 may be formed by an etch process, either isotropic or anisotropic etch process, and the etch process may be selective with respect to one or more crystalline planes of the substrate 101. The etch process may be a dry etch, such as a RIE, NBE, or the like, or a wet etch. The etchant from the etch process may include CH₂F₂, C₂F₆, CF₄, CHCl₃, SF₆, or the like or any suitable etchant.

FIGS. 7A-21E are cross-sectional views of the semiconductor device 100 taken along line A-A of FIG. 6, in accordance with some embodiments. Figures labeled with “A” The figures with figure numbers including “A” are for a PMOS region (e.g., 100A) in which p-type transistors are to be formed, and the figures with figure numbers including “B” are for an NMOS region (e.g., 100B) in which n-type transistors are to be formed. In some embodiment, the PMOS region includes an active region in an n-well (not shown), and the NMOS region includes an active regions in a p-well (not shown). For illustration purpose, hereinafter, the p-type devices (e.g., transistors) in the PMOS region (e.g., 100A) are referred to as p-FETs, and the n-type devices (e.g., transistors) in the NMOS region (e.g., 100B) are referred to as n-FETs, but those terms are not intended to limit the types of the semiconductor device in the present disclosure.

As shown in FIGS. 7A and 7B, the dummy gate structure 126 includes the dummy gate dielectric 128 and the dummy gate electrode 130, and the gate spacers 134 are formed on sidewalls of the dummy gate structures 126 in the PMOS region 100A and the NMOS region 100B. The gate spacer 134 may include the first gate spacer 135 and the second gate spacer 136. For clarity purposes, the hard mask 132 is not separately shown in the cross-sectional views of FIGS. 7A, 7B, and following figures.

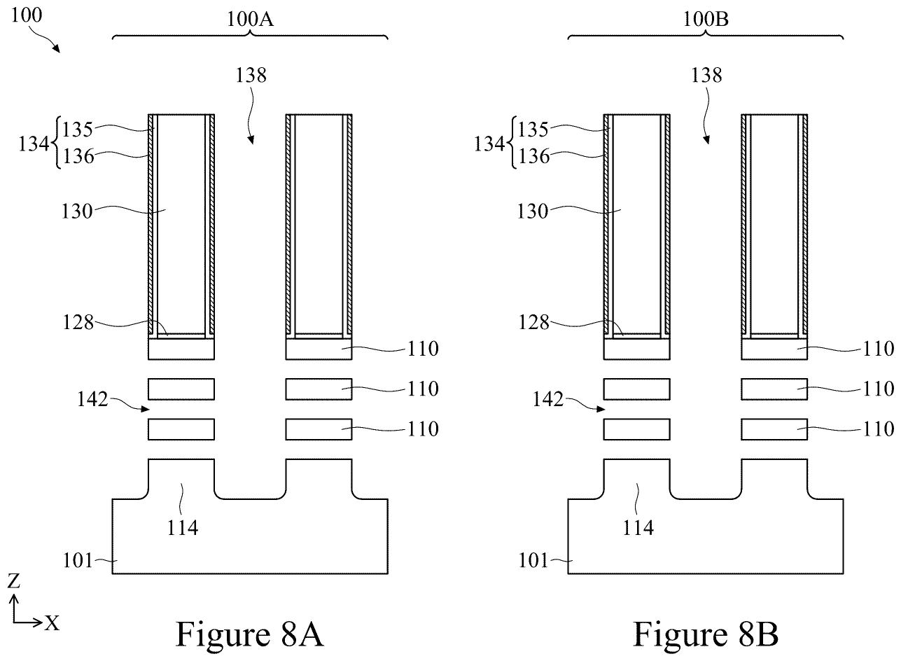

In FIGS. 8A and 8B, the second nanostructures 112 exposed by the first openings 138 are etched to form second openings 142 in the PMOS region 100A and the NMOS region 100B, in accordance with some embodiments. That is, the second openings 142 may be space that was occupied by the second nanostructures 112, including the space between the vertically adjacent first nanostructures 110 and between the bottommost first nanostructure 110 and the substrate 101. In an embodiment that the second semiconductor material includes, e.g., SiGe, an etch process using a hydroxide etchant, such as tetramethylammonium hydroxide (TMAH), ammonium hydroxide (NH₄OH), or the like, is used.

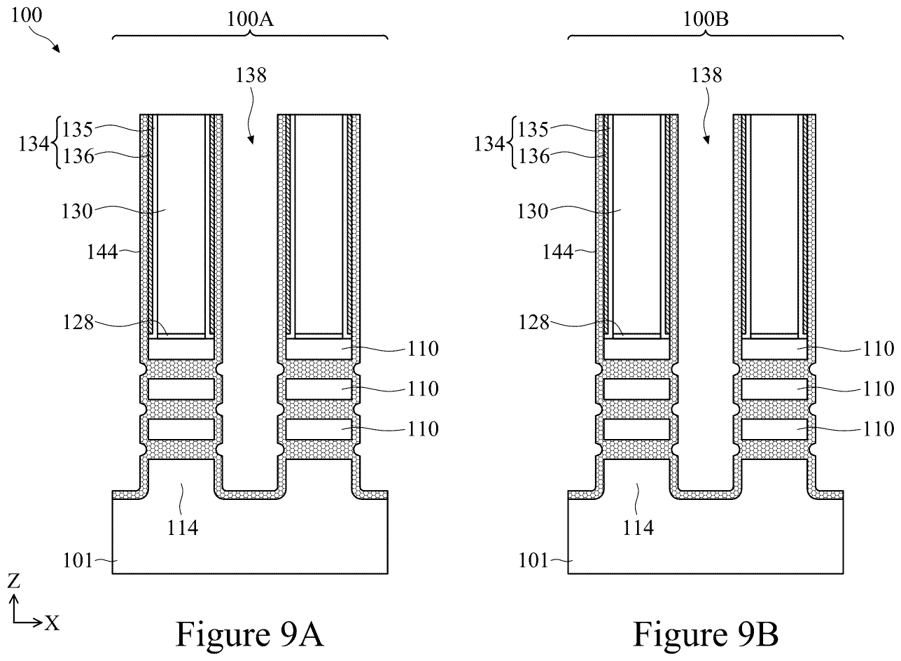

In FIGS. 9A and 9B, an insulating layer 144 is deposited in the first openings 138 and the second openings 142 in the PMOS region 100A and the NMOS region 100B, in accordance with some embodiments. Given the size differences between the first openings 138 and the second openings 142, the insulating layer 144 may substantially or completely fill the second openings 142 and form a conformal layer in the first openings 138. The insulating layer 144 may include an oxide-containing material, such as silicon oxide, silicon oxynitride, fluorine-doped silicate glass (FSG), a low-K dielectric material, or any suitable dielectric material. In some embodiments, the insulating layer 144 includes a material similar to those of the STI regions 120. The insulating layer 144 may be formed by any suitable depositing method, such as FCVD, ALD, PECVD, LPCVD, combinations thereof, or the like.

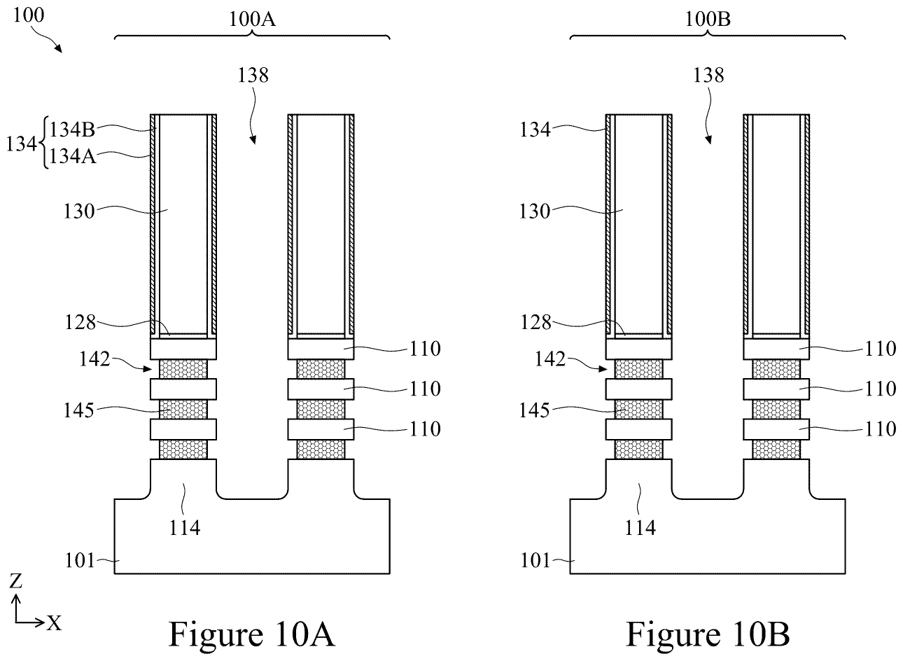

In FIGS. 10A and 10B, an etch process is performed to remove the insulating layer 144 in the first openings 138 and partially recess the insulating layer 144 in the second openings 142, thereby forming insulating nanostructures 145 in the second openings 142 in the PMOS region 100A and the NMOS region 100B, in accordance with some embodiments. The etch process may use etchants selective to etch the insulating layer 144, and the first nanostructures 110 and the substrate 101 may remain relatively unetched. The etch process may be an isotropic etch process. In some embodiments, the isotropic etch process is performed for a sufficient time to remove the insulating layer 144 in the first openings 138 and laterally recess the insulating layer 144 in the second openings 142. Accordingly, the insulating layer 144 is substantially or completely removed in the first openings 138. In an embodiment in which the insulating layer 144 remains in the first openings 138 after the isotropic etch process, a further anisotropic process may be performed to substantially or completely remove the insulating layer 144 in the first openings 138. For example, the isotropic etch process include an etchant including hydrofluoric acid, the like, a mixture therefore, or other suitable etchants.

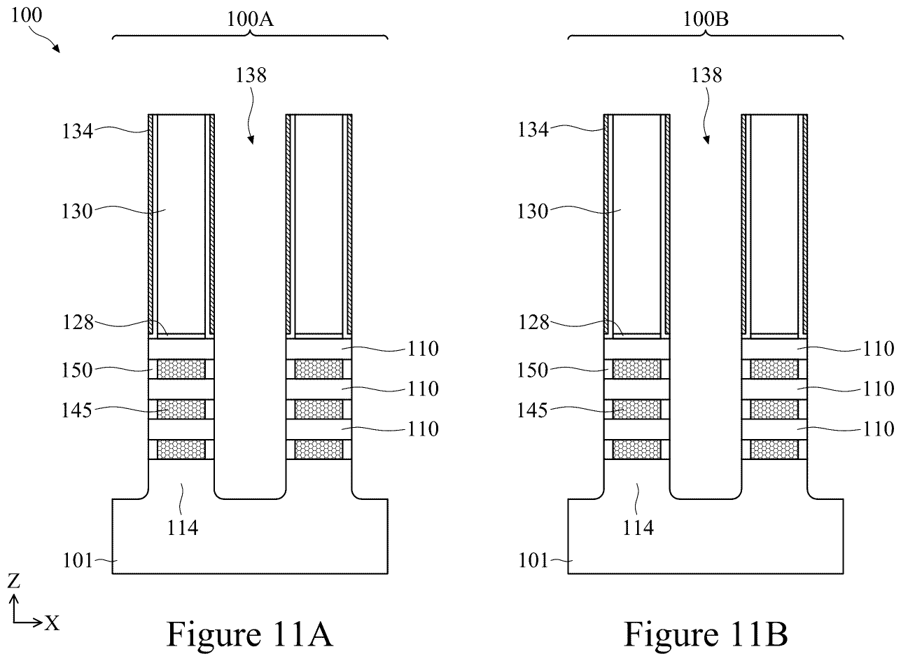

In FIGS. 11A and 11B, inner spacers 150 are formed in the lateral recesses and on the sidewalls of the insulating nanostructures 145 in the PMOS region 100A and the NMOS region 100B, in accordance with some embodiments. The inner spacers 150 may are insulating spacers acting as isolation features between subsequently formed epitaxial structures and a gate structure. As will be discussed in greater detail below, epitaxial structures will be formed in the first openings 138, and the insulating nanostructures 145 will be replaced with gate structures. Thus, the structural profiles of the gate structures may be determined by the structural profiles of the insulating nanostructures 145.

In some embodiments, an inner spacer layer is deposited by a conformal deposition process, such as CVD, ALD, or the like. The inner spacer layer may include a material such as silicon nitride, silicon oxynitride or silicon carbonitride, although any suitable material, such as a low-K dielectric material such as SiOC or SiOCN, may be utilized. The inner spacer layer may then be anisotropically etched to form the inner spacers 150, such as by RIE, NBE, or the like, using the gate spacers 134 as a mask. Although outer sidewalls of the inner spacers 150 are illustrated as being flush with sidewalls of the first nanostructures 110 in FIG. 11A, the outer sidewalls of the inner spacers 150 may extend beyond or be recessed from sidewalls of the first nanostructures 110. Moreover, although the outer sidewalls of the inner spacers 150 are illustrated as being straight in FIGS. 11A and 11B, the outer sidewalls of the inner spacers 150 may be concave or convex. The inner spacers 150 may have a thickness of about 3 nm to about 8 nm.

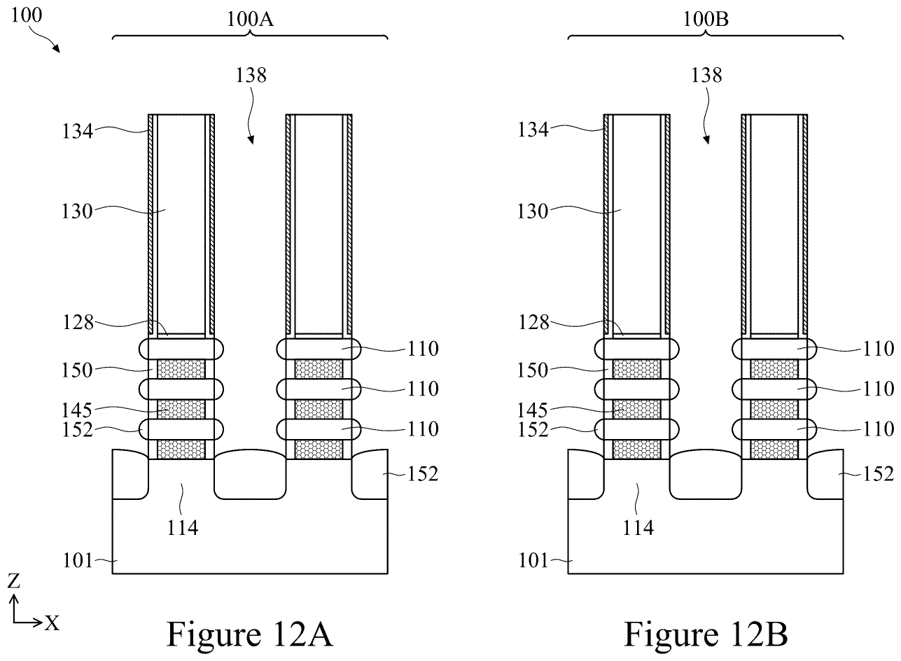

In FIGS. 12A and 12B, a buffer layer 152 is formed on the exposed substrate 101 in the first openings 138 in the PMOS region 100A and the NMOS region 100B, in accordance with some embodiments. The buffer layer 152 is or includes undoped silicon, undoped SiGe, or a combination thereof. In such embodiments, the buffer layer 152 may be formed by a selective epitaxial process, thereby selectively forming on semiconductor surfaces, such as on the exposed surfaces of the substrate 101 and the sidewall surfaces of the first nanostructures 110. Alternatively, the buffer layer 152 is or includes an insulator such as silicon oxide, silicon nitride, silicon oxynitride, or a combination thereof.

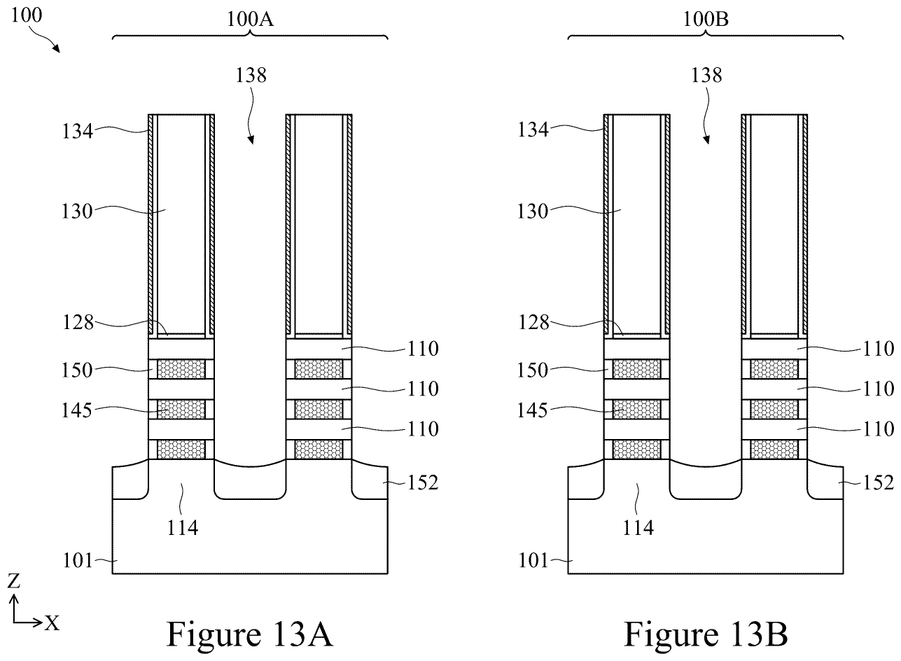

In FIGS. 13A and 13B, a subsequent etch process is performed to remove portions of the buffer layer 152 formed on the sidewall surfaces of the first nanostructures 110. The etch process may also etch portions of the buffer layer 152 at the bottom of the first openings 138. The etch process may include a dry etch process such as RIE, NBE, or the like. The etch process may substantially remove the buffer layer 152 on the sidewall surfaces of the first nanostructures 110 and partially etch the buffer layer 152 at the bottom of the first openings 138. Thus, portions of the buffer layer 152 may remain at the bottom of the first openings 138 after the etch process. The remaining portions of the buffer layer 152 may reduce the current leakage or dopant diffusion from the subsequently formed source/drain regions. In some embodiments, the buffer layer 152 has a concave upper surface due to the etch process. The buffer layer 152 may have a thickness ranging from about 5 nm to about 50 nm along the Z direction. Although FIGS. 13A and 13B show the buffer layer 152 has a top surface lower than the lowermost inner spacer 150, the top surface of the buffer layer 152 may overlap the lowermost inner spacer 150 in the Z-direction.

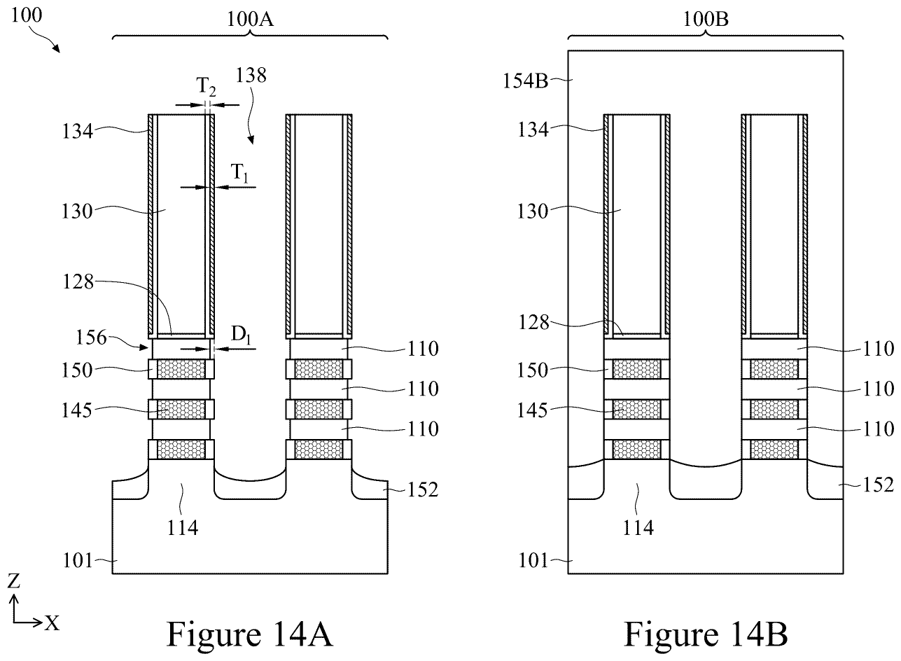

In FIGS. 14A and 14B, a mask layer 154B is applied to the NMOS region 100B to mask the structure in the NMOS region 100B, and an etch process is performed to laterally recess the first nanostructures 110 in the PMOS region 100A, in accordance with some embodiments. The mask layer 154B may include a photoresist layer. The lateral recessing for the first nanostructures 110 may include an isotropic etch process that has a good etch selectivity with the insulating nanostructures 145, the dummy gate dielectric 128, and the gate spacers 134, e.g., with a ratio of etch rate may be greater than 50, or over 100. As such, the at least insulating nanostructures 145 would not be substantially damaged by the lateral recessing, so that the predetermined structural profiles of the gate structures would not be affected by the lateral recessing. In an exemplary embodiment, the etch process is a wet etch using etchants comprising KOH, NaOH, a mixture thereof, or the like.

The lateral recessing for the first nanostructures 110 may create lateral recesses 156 with a recess depth D₁ measured from a sidewall of the recessed first nanostructures 110 to an outer sidewall of the gate spacers 134 (e.g., sidewall surface facing away the dummy gate electrode 130). The recess depth D₁ may be controlled by the etching time. In some embodiments, recess depth D₁ is less than the thickness of the gate spacer 134. Accordingly, after the lateral recessing, the sidewall of the first nanostructures 110 is between an inner sidewall of the gate spacer 134 (e.g., facing the dummy gate electrode 130) and the outer sidewall of the gate spacer 134. In some embodiments, the recess depth D₁ is greater than the thickness T₁ of the first gate spacer 135 but less than the total thickness of the gate spacer 134. In some embodiments, the recess depth D₁ is smaller than the thickness T₁ of the fist gate spacer 135. For example, the recess depth D₁ is in a range from about 2 nm to about 10 nm. It is appreciated that although FIG. 14A shows the sidewall surfaces of the first nanostructure 110 are perpendicular surfaces, it is understood that the sidewall surfaces of the first nanostructure 110 may be curved surfaces, depending on the characteristics of the process of the later recessing.

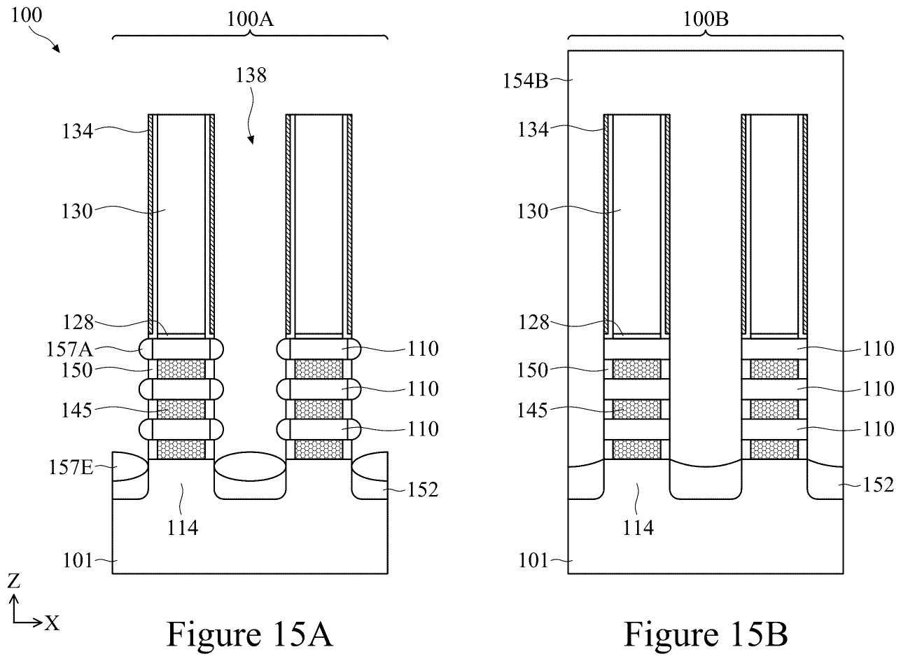

Next, in FIGS. 15A and 15B, p-type source/drain extension regions 157A are formed in the lateral recess 156 in the PMOS region 100A, in accordance with some embodiments. The p-type source/drain extension regions 157A may be formed by a selective epitaxial process, thereby selectively forming on semiconductor surfaces. Thus, when forming the p-type source/drain extension regions 157A on the sidewall surfaces of the first nanostructures 110, epitaxial features 157E are together formed on the exposed surfaces of the buffer layer 152. As illustrated in FIG. 15A, each of p-type source/drain extension regions 157A may be separated from each other as well as being separated from the epitaxial features 157E.

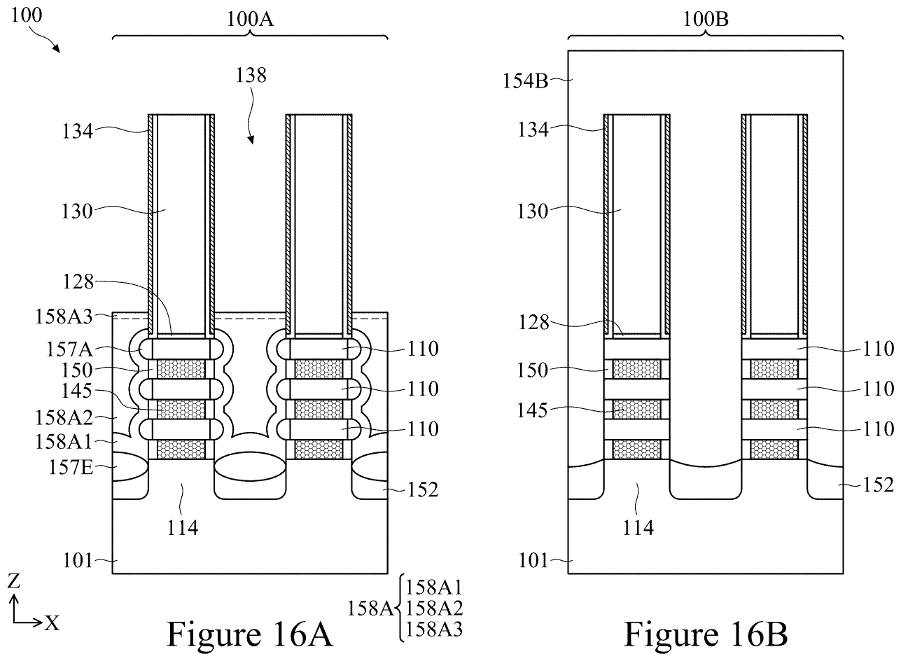

The outer sidewall surfaces (i.e., surfaces away from the first nanostructure 110) of each of the p-type source/drain extension regions 157A may be curved surfaces, although these outer sidewall surfaces can be straight surfaces (e.g., substantially perpendicular to the major surface of the substrate 101). As illustrated in FIG. 15A, the outer sidewall surfaces of the p-type source/drain extension regions 157A may protrude over the outer sidewall surfaces of the inner spacers 150 in a lateral direction (e.g., X-direction). In some embodiments, at least one of the outer sidewall surfaces of the p-type source/drain extension regions 157A does not protrude over the outer sidewall surfaces of the inner spacers 150 in the lateral direction so as to provide more space for the p-type S/D regions 158A (FIG. 16A) to be formed in the first openings 138, reducing the risks for forming seam in the p-type S/D regions 158A. In such embodiments, the p-type S/D regions (158A, FIG. 16A) may be in contact with the upper surfaces of the inner spacers 150 and/or the bottom surfaces of the gate spacers 134. It is also appreciated that, depending on design requirements, and being controlled by the epitaxial deposition thicknesses, the outer sidewall surfaces of the p-type source/drain extension regions 157A may completely protrude over the outer sidewall surfaces of the inner spacers 150 in the lateral direction. In an embodiment, the epitaxial feature 157E has a convex upper surface. In some embodiments, the epitaxial feature 157E has a convex bottom surface.

The p-type source/drain extension regions 157A may be or include a SiGe material. In some embodiments, the p-type source/drain extension regions 157A have a germanium concentration in a range of about 6 at % to about 20 at %. The p-type source/drain extension regions 157A may be doped with suitable p-type dopants, such as boron, with a range of 3E20-1E21 cm⁻³, although higher or lower boron concentration may be implemented. In an embodiment, each of the p-type source/drain extension regions 157 has a gradient germanium concentration. In exemplary embodiments, the p-type source/drain extension regions 157A have a gradually increased germanium concentration in a lateral direction away from the first nanostructures 110, and the epitaxial features 157E have a gradually increased germanium concentration in a vertical direction away from the buffer layer 152. As compared to silicon, germanium has better electrical conductivity. Thus, to include germanium in the p-type source/drain extension regions 157A may increase the electrical conductivity, thereby improving the device performance. Suitable concentration of germanium in the p-type source/drain extension regions 157A (e.g., over 6 at %) may also reduce the dopant to be diffused into channels of the P-FETs (e.g., first nanostructures). Thus, the p-type dopants in the p-type source/drain extension regions 157A may have abrupt doping profile junctions adjacent to the channel regions, which can also reduce the electrical resistance of the p-type source/drain extension regions 157A.

Next, as shown in FIGS. 16A and 16B, p-type source/drain (S/D) regions 158A are formed over the substrate 101, such as in the first openings 138 in the PMOS region 100A. In some embodiments, the p-type S/D regions 158A grow to form facets, which may correspond to crystalline planes of the material used for the substrate 101. In this disclosure, a source region and a drain region are interchangeably used, and the structures thereof are substantially the same. Furthermore, source/drain region(s) may refer to a source or a drain, individually or collectively dependent upon the context.

In some embodiments, the p-type S/D regions 158A are p-type epitaxial features. The p-type S/D regions 158A may be formed by an epitaxial growth method using CVD, ALD, or MBE. In some embodiments, the p-type S/D regions 158A include a plurality of epitaxial layers, such as a first layer 158A1, a second layer 158A2, and an optional third layer 158A3. In some embodiments, each of the first layer 158A1, the second layer 158A2, and the third layer 158A3 are formed by multiple cycles (so called “cyclic deposition and etching processes”), and each cycle may include deposition operations and etching operations performed alternately or simultaneously. The dopants may be introduced in situ as the p-type S/D regions 158A being grown epitaxially.

The formation of the p-type S/D regions 158A may include firstly depositing the first layer 158A1. The first layer 158A1 may be a continuous layer covering the p-type source/drain extension regions 157A, the epitaxial features 157E, and the inner spacers 150 in the first openings 138 in the PMOS region 100A. For example, the first layer 158A1 may physically connect and electrically couple all the p-type source/drain extension regions 157A and the epitaxial features 157E in one first opening 138. In some embodiments, the first layer 158A1 has a relatively thick thickness on the p-type source/drain extension regions 157A and a relatively thin thickness on the inner spacers 150. The first layer 158A1 may have a thickness ranging from about 2 nm to about 5 nm.

Following formation of the first layer 158A1, the second layer 158A2 is formed on the first layer 158A1. For example, the second layer 158A2 may fill in a cavity surrounded by the first layer 158A1. The second layer 158A2 may further extend to cover upper surfaces of the first layer 158A1. Following formation of the second layer 158A2, a third layer 158A3 is formed on the second layer 158A2. The third layer 158A3 may cover the second layer 158A2.

The epitaxial growth processes for forming the first layer 158A1, the second layer 158A2, and the third layer 158A3 may be similar but may use different use different ratios of reaction gases and dopants. For example, the Ge concentration of the first layer 158A1 of the p-type source/drain regions 158 is higher than Ge concentration of the p-type source/drain extension region 157A. The Ge concentration of the second layer 158A2 of the p-type S/D regions 158A is higher than Ge concentration of the first layer 158A1 and the third layer 158A3 of the p-type source/drain regions 158. In some embodiments, the first layer 158A1 of the p-type source/drain regions 158 has Ge concentration ranging from about 15 at % to about 30 at %, and the second layer 158A1 has Ge concentration ranging from about 30 at % to about 70 at %. The third layer 158A3 may have Ge concentration ranging from about 20 at % to about 40 at %. In an embodiment, the second layer 158A2 has a gradient Ge concentration from bottom to up. In some embodiments, the p-type source/drain extension regions 157A and the second layer 158A2 of the p-type S/D regions 158A both have gradient Ge concentrations, and the first layer 158A1 and the third layer 158A3 of p-type S/D regions 158A both have fixed Ge concentrations. The first layer 158A1 may be doped with p-type dopants (e.g., boron) in range of about 3E20 to about 1E21 cm⁻³, and the second layer 158A2 may be doped with p-type dopants (e.g., boron) in range of about 5E20 to about 1E22 cm⁻³. Although three layers are illustrated in the exemplary embodiments here, the number of layers in the p-type S/D regions 158A is not limited, and more or fewer layers can be implemented. The p-type S/D regions 158A may generate a compressive stress to the channel regions (e.g., the first nanostructures 110 between the p-type source/drain extension regions 157A) of the semiconductor device 100, and the SiGe material of the p-type S/D regions 158A can be also replaced with other suitable semiconductor layers that have good conductivity and can exert compress stress to the channel regions. For example, in some embodiments, Ge may be replaced with Sn in the p-type S/D regions 158A.

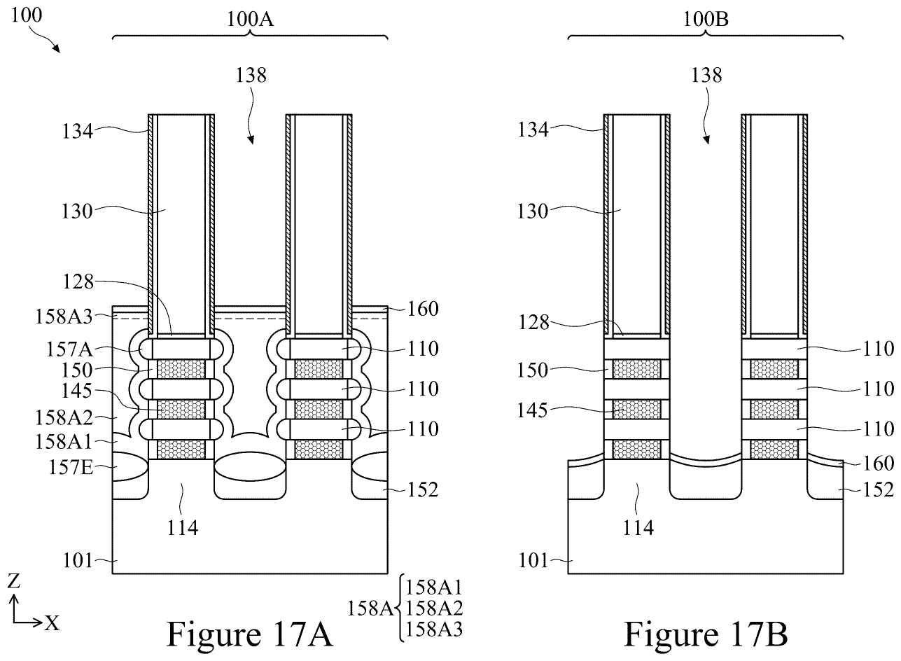

Next, as shown in FIGS. 17A and 17B, the mask layer 154B covering the NMOS region 100B is removed, and an insulating layer 160 is deposited over the p-type S/D regions 158A in the PMOS regions 100P and over the buffer layer 152 in the NMOS region 100B, in accordance with some embodiments. The mask layer 154B may be removed by any suitable process, such as an ashing and/or an etch process. The insulating layer 160 may be or include an insulating material such as silicon oxide, silicon nitride, silicon carbide, silicon oxynitride, silicon oxycarbide. The insulating layer 160 may be formed by ALD, CVD, or other suitable techniques. The insulating layer 160 may be a conformal layer and has a thickness of about 1 nm to about 5 nm. The insulating layer 160 may reduce leakage current in the NMOS region 100B and may also prevent or reduce dopant diffusion in the PMOS region 100A and the NMOS region 100B.

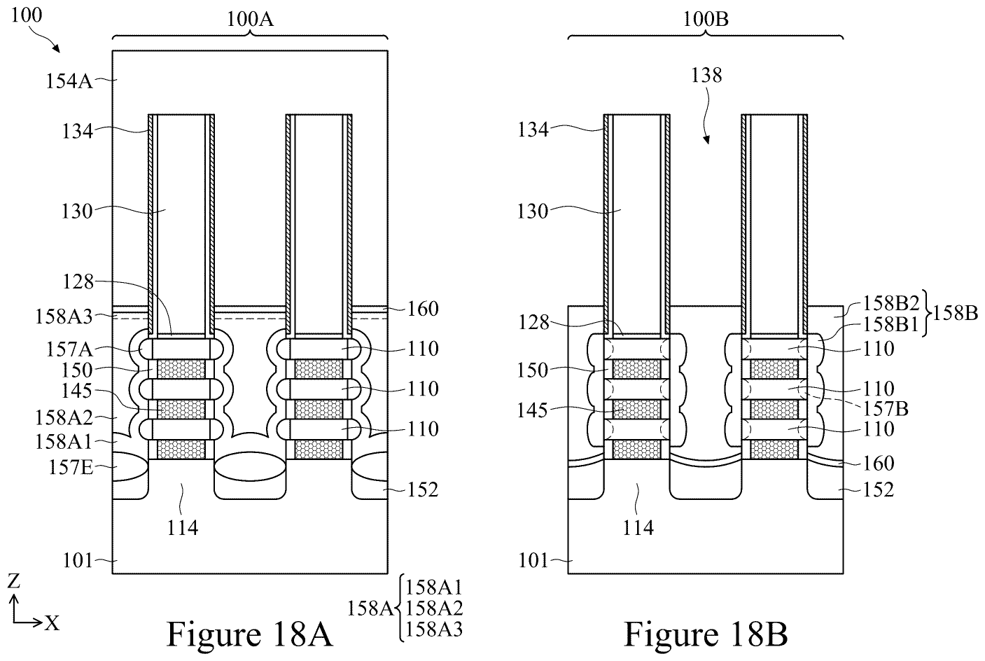

Next, in FIGS. 18A and 18B, the PMOS region 100A is masked by a mask layer 154A, and n-type S/D regions 158B are formed in NMOS regions 100B, in accordance with some embodiments. The n-type S/D regions 158B may be n-type source/drain epitaxial features and doped with n-type dopants such as P or As. For example, the n-type S/D regions 158B may be made of one or more epitaxial layers. In some embodiments, the n-type S/D regions 158B includes a first layer 158B1 and a second layer 158B2 , which may be formed by an epitaxial growth method using CVD, ALD, or MBE. The first layer 158B1 may be a continuous layer covering the side surfaces of the first nanostructures 110 and the inner spacers 150 in the NMOS region 100B. For example, each of the first layers 158B1 may physically connect to two or more side surfaces of the first nanostructures 110 in the first openings 138 (FIG. 17B). In some embodiments, the first layer 158B1 has relatively thick thicknesses on the side surfaces of the first nanostructures 110 and relatively thin thicknesses on the inner spacers 150. In some embodiments, in respective one first opening 138, two or more first layers 158B1 are formed and not merged. In an embodiment, the first layers 158B1 are in contact with the insulating layer 160 but do not completely cover the upper surface of insulating layer 160. In some embodiments, the first layers 158B1 are not in contact with the insulating layer 160. The second layer 158B2 may be formed on the first layers 158B1 and the insulating layer 160. For example, the second layer 158B2 may fill in a cavity laterally surrounded by the first layers 158B1.

In an embodiment, the epitaxial features of the n-type S/D regions 158B are formed of Si. In some embodiments, the n-type source/drain regions may include material that can exert tensile stress to the channel regions (e.g., first nanostructure 110 in the NMOS region 100B), such as SiC or other suitable materials. In such embodiments that SiC is used, the first layer 158B1 includes carbon concentration of 15-30 at %, and the second layer 158B2 includes carbon concentration of 30-70 at %. In some embodiments, the first layer 158B1 have the n-type dopants ranging from about 3E20 to about 1E21 cm⁻³, and the second layer 158B2 have n-type dopants ranging from about 5E20 to about 1E22 cm⁻³. Although two epitaxial layers 158B1 and 158B2 are illustrated in FIGS. 18A and 18B, the number of the epitaxial layers is not limited thereto.

Before the formation of n-type S/D regions 158B, n-type source/drain extension regions 157B is formed in the first nanostructures 110 in the NMOS region 100B, in accordance with some embodiments. The n-type source/drain extension regions 157B may be formed by an ion-implantation processes. The ion implantation process may use suitable tilt angle to implant N-type dopants such as P or As into the first nanostructures 110. The n-type source/drain extension regions 157B may have a dopant concentration ranging from 3E20-1E21 cm⁻³. In such embodiments, the n-type source/drain extension regions 157B are disposed in the first nanostructures 110, and the channel regions of n-FETs are disposed in the first nanostructures 110 and interposed by the n-type source/drain extension regions 157B. In an embodiment, the mask layer 154A covering the PMOS region 100A is removed after the n-type S/D regions 158B are formed. The mask layer 154A may be removed, for example, by an ashing process and/or an etch process.

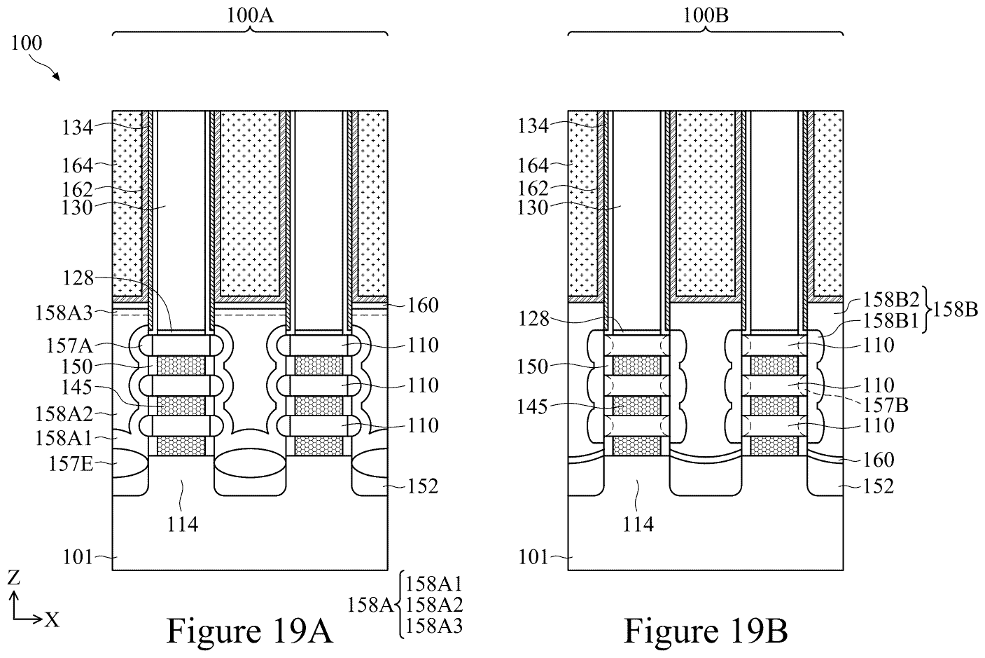

In FIGS. 19A and 19B a contact etch stop layer (CESL) 162 is conformally formed on the exposed surfaces of the semiconductor device 100, in accordance with some embodiments. The CESL 162 covers the STI regions 120, the source/drain regions 158, and the sidewalls of the gate spacers 134. The CESL 162 may include an oxygen-containing material or a nitrogen-containing material, such as silicon nitride, silicon carbon nitride, silicon oxynitride, silicon oxycarbide, combinations thereof, or the like. The CESL 162 may be formed by CVD, PECVD, ALD, or any suitable deposition technique. Next, a first interlayer dielectric (ILD) layer 164 is formed on the CESL 162 over the semiconductor device 100. The materials for the first ILD layer 164 may include compounds including Si, O, C, and/or H, such as silicon oxide, SiCOH, PSG, BSG, BPSG, combinations thereof, or the like. Organic materials, such as polymers, may also be used for the first ILD layer 164. The first ILD layer 164 may be deposited by FCVD, PECVD, or other suitable deposition techniques. In some embodiments, after the first ILD layer 164 is deposited, a thermal process is performed to cure the first ILD layer 164. After the first ILD layer 164 is formed, a planarization operation, such as CMP, is performed to level the top surface of the first ILD layer 164 with the top surfaces of dummy gate electrodes 130 or the hard masks 132. In some embodiments in which the hard masks 132 remain, the planarization process levels the top surface of the first ILD layer 164 with the top surfaces of the hard masks 132 and the gate spacers 134. In some embodiments, top surfaces of the dummy gate electrodes 130, the gate spacers 134, and the first ILD layer 164 are level within process variations after the planarization process. In such embodiments, the top surfaces of the dummy gate electrodes 130 are exposed through the first ILD layer 164.

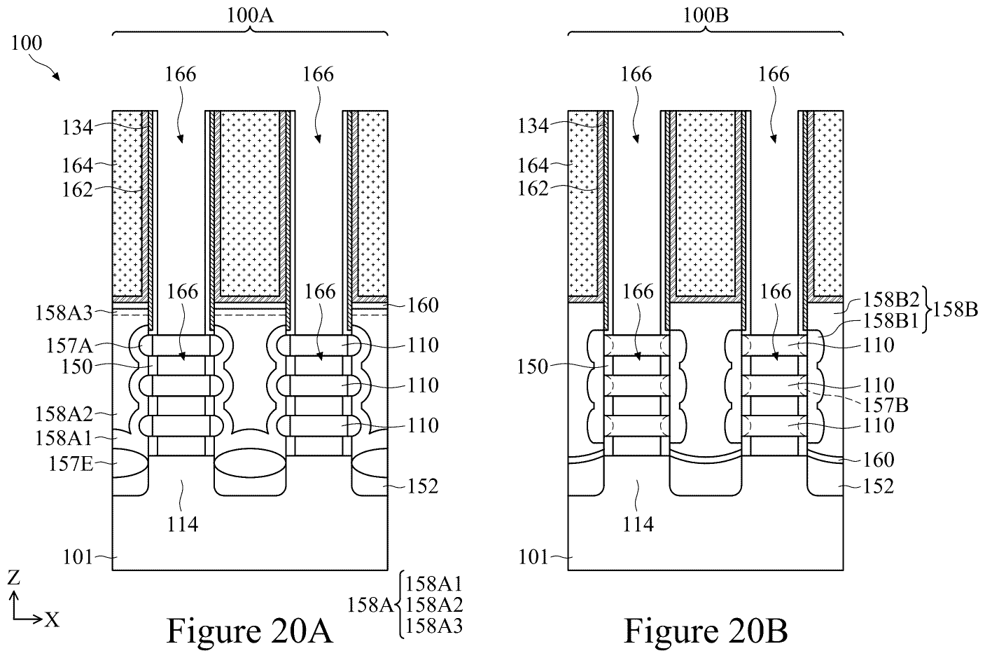

In FIGS. 20A and 20B, the dummy gate electrodes 130, the hard masks 132 (if exist), and the insulating layer 144 are removed. In some embodiments, the dummy gate dielectrics 128 are also removed after the dummy gate electrodes 130 are removed. The hard masks 132, the dummy gate electrodes 130 and the dummy gate dielectrics 128 may be removed by one or more etch processes. For example, an etch process may be performed by etching the hard masks 132 using the dummy gate electrodes 130 as an etch stop, etching the dummy gate electrodes 130 using the dummy gate dielectrics 128 as an etch stop, and the dummy gate dielectrics 128 are then removed by another etch process. In some embodiments, the etch process for etching the dummy gate electrodes 130 and the dummy gate dielectrics 128 may include using reaction gas(es) that selectively etch the dummy gate electrodes 130 and the dummy gate dielectrics 128 at a faster rate than the first ILD layer 164 or the gate spacers 134.

After the dummy gate dielectrics 128 and the dummy gate electrodes 130 are removed, the insulating nanostructures 145 are exposed, and an isotropic etch process may be performed to remove the insulating nanostructures 145. The isotropic etch process may include a wet etching containing an etchant containing a dilute HF or other suitable etchants. The removal of the hard masks 132, the dummy gate electrodes 130, the dummy gate dielectrics 128, and the insulating nanostructures 145 forms third openings 166.

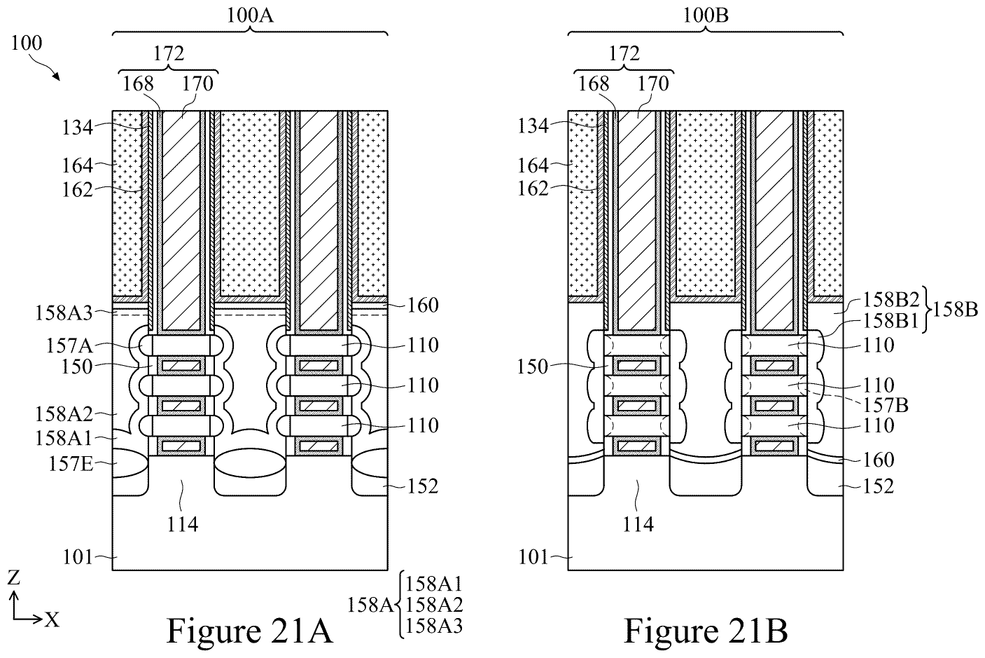

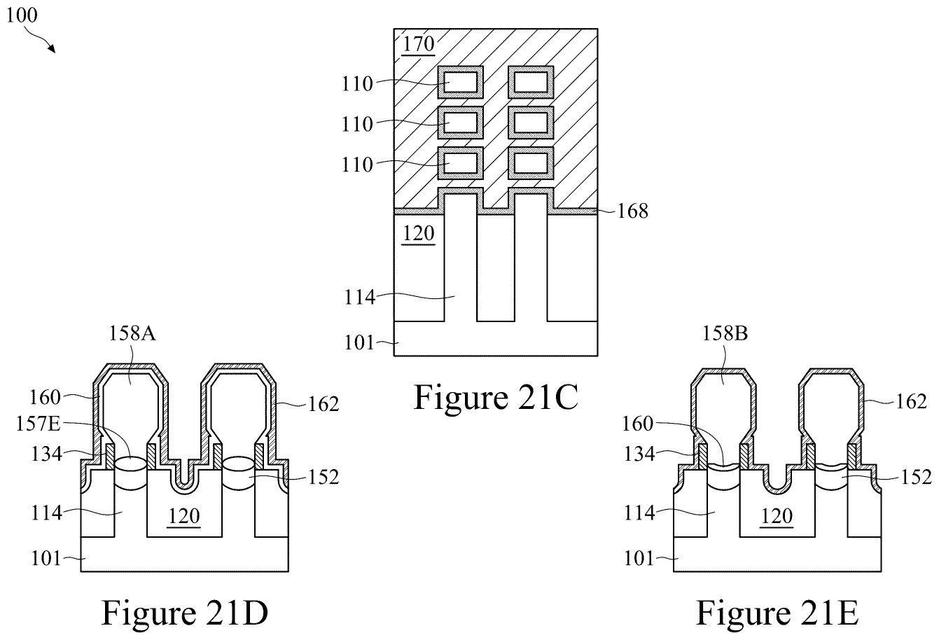

Next, in FIGS. 21A and 21B, gate dielectric layers 168 and gate electrodes 170 are formed for replacement gates, in accordance with some embodiments. FIGS. 21C-21E are also illustrated for the corresponding cross-sectional views of the semiconductor device 100 at the current stage. FIG. 21C illustrates the corresponding cross-sectional view of the semiconductor device 100 along the sections B-B as illustrated in FIG. 6 (can represent either in the PMOS region 100A or in the NMOS region 100B). FIG. 21D illustrates the corresponding view of the semiconductor device 100 along the sections C-C of FIG. 6 in the PMOS region 100A, and FIG. 21E illustrates the corresponding view of the semiconductor device 100 along the sections C-C of FIG. 6 in the NMOS region 100B.

The gate dielectric layers 168 are deposited conformally in the third openings 166. The gate dielectric layers 168 may be formed on top surfaces and sidewalls of the substrate 101 and on exposed surfaces of the first nanostructures 110, In some embodiments, the gate dielectric layers 168 are also deposited on top surfaces of the first ILD layer 164, the CESL 162, the gate spacers 134, and the STI regions 120. In some embodiments, the gate dielectric layers 168 include one or more layers of a dielectric material, such as silicon oxide, silicon nitride, or high-K dielectric material, other suitable dielectric material, and/or combinations thereof. Examples of high-K dielectric material include HfO, HfSiO, HfSiON, HfTaO, HfTiO, HfZrO, zirconium oxide, aluminum oxide, titanium oxide, hafnium oxide-alumina (HfO—AlO) alloy, other suitable high-K dielectric materials, and/or combinations thereof. The gate dielectric layers 168 may be formed by CVD, ALD, or any suitable deposition techniques.

The gate electrodes 170 are deposited over the gate dielectric layer 168, respectively, and fill the remaining portions of the third openings 166. The gate electrodes 170 may include a metal-containing material such as titanium nitride, titanium oxide, tantalum nitride, tantalum carbide, cobalt, ruthenium, aluminum, tungsten, combinations thereof, or multi-layers thereof. Although single-layer gate electrodes 170 are illustrated in FIGS. 21A and 21B, the gate electrodes 170 may comprise any number of liner layers, any number of work function tuning layers, and a fill material. The gate electrodes 170 may be formed by CVD, ALD, electro-plating, or other suitable deposition techniques. After filling the third openings 166, excess materials of the gate dielectric layers 168 and the gate electrodes 170 over the top surface of the first ILD layer 164 are then removed by a planarization process, such as CMP, until the top surfaces of the first ILD layer 164 are exposed. The remaining portions of the gate electrodes 170 and the gate dielectric layers 168 thus form replacement gate structures of the semiconductor device 100. The gate electrodes 170 and the gate dielectric layers 168 may be collectively referred to as gate structures 172. The gate structures 172 may surround channels (e.g., the first nanostructures 110) of the semiconductor device 100.

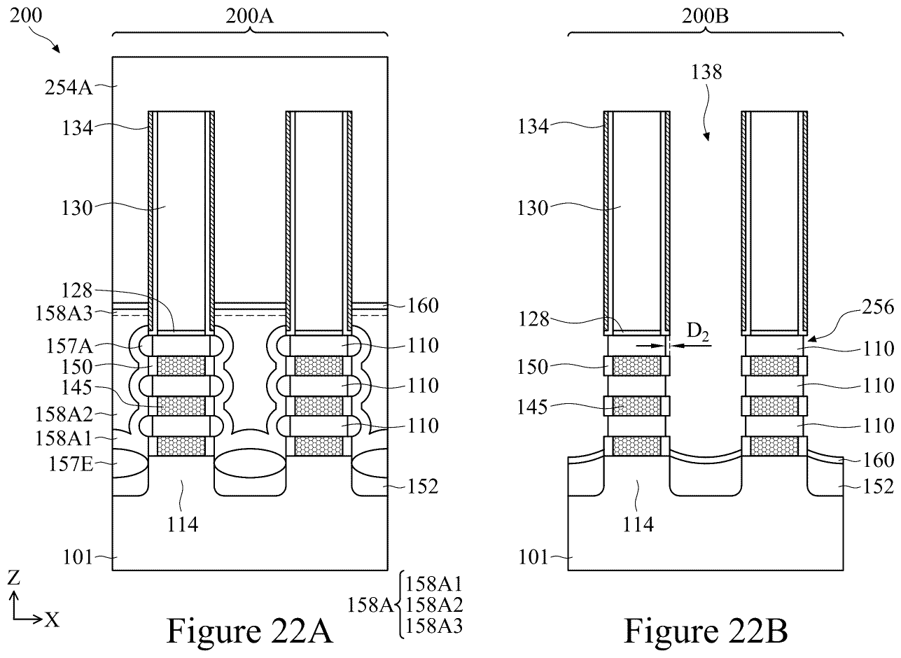

FIGS. 22A to 25B illustrate cross-sectional views of intermediate stages in manufacturing a semiconductor device 200, in accordance with some embodiments. The semiconductor device 200 is similar to the semiconductor device 100, wherein same reference numeral represents same elements. In the semiconductor device 200, p-FETs are formed in a PMOS region 200A, and n-FETs are formed in an NMOS region 200B. In some embodiments, the n-FETs in the NMOS region 200B include n-type source/drain extension regions 257B that are formed of epitaxial features.

The processes for forming the n-type source/drain extension regions 257B are similar to those of forming the p-type source/drain extension regions 157A. For example, formation of the semiconductor device 200 may include similar processes may proceeding From FIG. 1 to FIG. 17B. Thereafter, referring to FIGS. 22A and 22B, the mask layer 254A is applied to the PMOS region 200A to mask the structure in the PMOS region 200A, and an etch process is performed to laterally recess the first nanostructures 110 in the NMOS region 200B, in accordance with some embodiments. The mask layer 254A may include a photoresist layer. The lateral recessing for the first nanostructures 110 in the NMOS region 200B may include an isotropic etch process that has a good etch selectivity with the insulating nanostructures 145, the dummy gate dielectric 128, and the gate spacers 134, e.g., with a ratio of etch rate may be greater than 50, or over 200. For example, the etch process may be a wet etch with etchants comprising KOH, NaOH, a mixture thereof, or the like. The lateral recessing may create lateral recesses 56 with a recess depth D₂ measured from a sidewall of the recessed first nanostructures 110 to a sidewall surface of the gate spacers 134. The recess depth D₂ may be controlled by the etching time. In some embodiments, recess depth D₂ is less than the thickness of the gate spacer 134. In some embodiments, the recess depth D₂ is substantially the same as the recess D₁, although different recess depths may be implemented. Accordingly, after the lateral recessing, outer sidewall surfaces of the first nanostructures 110 are between an inner sidewall of the gate spacer 134 (facing the dummy gate electrode 130) and an outer sidewall of the gate spacer 134 (away from the dummy gate electrode 130). In some embodiments, the recess depth D₂ is greater than the thickness T₁ of the first gate spacer 135 but less than the total thickness of the gate spacer 134. In some embodiments, the recess depth D₂ is smaller than the thickness T₁ of the fist gate spacer 135. For example, the recess depth D₂ is in a range from about 2 nm to about 10 nm. It is appreciated that although FIGS. 22A and 22B show the sidewall surfaces of the first nanostructure 110 are perpendicular surfaces, the sidewall surfaces of the first nanostructure 110 may be curved surfaces, depending on the characteristics of the lateral recessing processes.

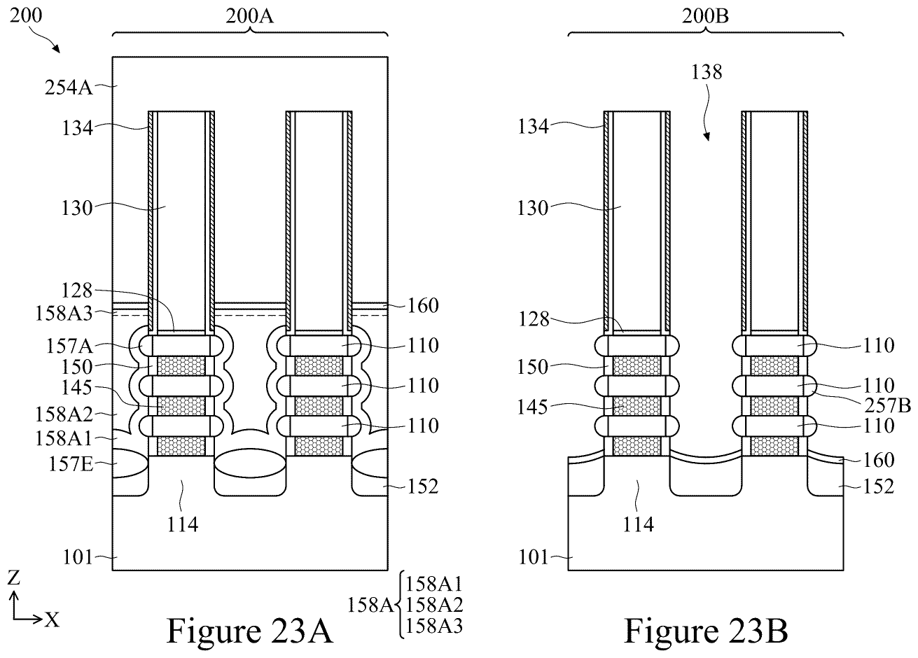

Next, in FIGS. 23A and 23B, n-type source/drain extension regions 257B are formed in the lateral recesses 256 in the NMOS region 200B, in accordance with some embodiments. The n-type source/drain extension regions 257B may be formed by a selective epitaxial process, thereby selectively forming on semiconductor surfaces, such as sidewall surfaces of the first nanostructures 110. Because the buffer layer 152 is covered by the insulating layer 160, epitaxial features may not be formed on the buffer layer 152 when forming the n-type source/drain extension regions 257B. As illustrated in FIG. 22B, each of the n-type source/drain extension regions 257B are separated from each other as well as being separated.

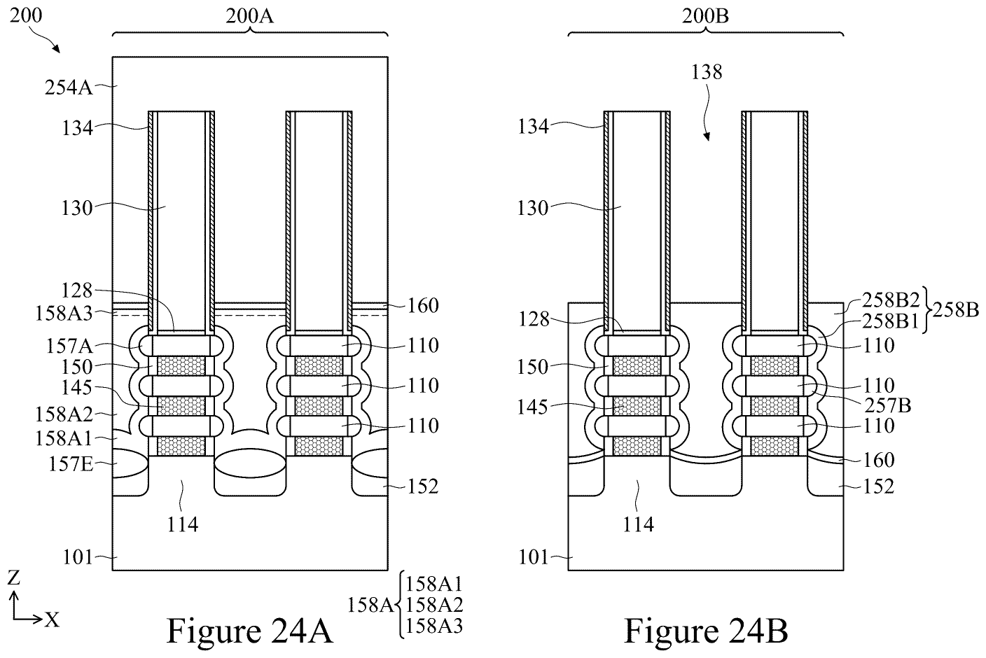

The outer sidewall surfaces (i.e., surfaces away from the first nanostructure 110) of each of n-type source/drain extension regions 257B may be curved surfaces, although these outer sidewall surfaces can be straight surfaces (e.g., substantially perpendicular to the major surface of the substrate 101). As illustrated in FIG. 23B, the outer sidewall surfaces of the n-type source/drain extension regions 257B may protrude over the outer sidewall surfaces of the inner spacers 150. In some embodiments, at least one of the outer sidewall surfaces of the n-type source/drain extension regions 257B may not protrude over the outer sidewall surfaces of the inner spacers 150 in a lateral direction (e.g., X-direction) so as to provide more space for the n-type S/D regions 258B (FIG. 24B) to be formed in the first openings 138, reducing the risks for forming seam in the subsequently formed n-type S/D regions 258B. In some embodiments, the subsequently formed n-type S/D regions 258B are in contact with upper surfaces of the inner spacers 150 and/or the bottom surfaces of the gate spacers 134 in the NMOS region 200B, It is also appreciated that, depending on design requirements and being controlled by the epitaxial deposition thicknesses, the outer sidewall surfaces of the n-type source/drain extension regions 257B may completely protrude over the outer sidewall surfaces of the inner spacers 150 in the lateral direction, in accordance with some embodiments.

The n-type source/drain extension regions 257B may be or include a SiC material. In some embodiments, the n-type source/drain extension regions 257B have a carbon concentration in a range of about 6 at % to about 20 at %. The n-type source/drain extension regions 257B may be lightly doped with suitable n-type dopants, such as P or As, with a range of 3E20-1E21 cm⁻³. In some embodiments, each of n-type source/drain extension regions 257B has a gradient carbon concentration. For example, the n-type source/drain extension regions 257B may have a gradually increased carbon concentration in a lateral direction away from the first nanostructures 110. As compared to silicon, carbon has better electrical conductivity and better performance to reduce dopant diffusion (e.g., phosphorous). Thus, to include carbide in the n-type source/drain extension regions 257B may increase the electrical conductivity and to reduce dopant extrusion into channels of the semiconductor device 200.

Next, process as shown in FIGS. 24A and 24B, n-type source/drain (S/D) regions 258B are formed over the substrate 101, such as in the first openings 138 in the NMOS region 200B. In some embodiments, the n-type S/D regions 258B are n-type epitaxial features, which may be formed by an epitaxial growth method using CVD, ALD, or MBE. In some embodiments, the n-type S/D regions 258B each includes a plurality of epitaxial layers, such as a first layer 258B1 and a second layer 258B2 as illustrated in FIGS. 24A and 24B. In some embodiments, an optional third layer is also included the n-type S/D regions 258B. Each of the first layer 258B1 and the second layer 258B2 may be formed by multiple cycles (so called “cyclic deposition and etching processes”), and each cycle may include deposition operations and etching operations performed alternately or simultaneously.

The formation of the n-type S/D regions 258B may include firstly depositing the first layer 258B1. The first layer 258B1 may be a continuous layer covering the n-type source/drain extension regions 257B and the inner spacers 150 in the first openings 138 in the NMOS region 200B. In some embodiments, in one respective one first opening 138, two or more first layers 258B1 are formed and not merged, and at least a portion of the upper surface of the insulating layer 160 is not covered by the first layers 258B1. Each of the first layer 258B1 of the n-type S/D regions 258B may physically connect to and electrically couple to multiple n-type source/drain extension regions 257B. In some embodiments, the first layer 258B1 may have a relatively thick thickness on the n-type source/drain extension regions 257B and a relatively thin thickness on the inner spacers 150.

Following the formation of the first layers 258B1, the second layer 258B2 is formed on the first layers 258B1. For example, the second layer 258B2 may fill in a cavity laterally surrounded by the first layers 258B1. The second layer 258B2 may further extend to cover upper surfaces of the first layers 258B1. Following the formation of the second layer 258B2, the third layer (if present) may be formed on the second layer 258B2.

The epitaxial growth processes for forming the first layer 258B1 and the second layer 258B2 may be similar but may use different use different ratios of reaction gases and dopants. For example, the carbon concentration of the first layer 258B1 is higher than carbon concentration of the n-type source/drain extension region 257B. The carbon concentration of the second layer 258B2 is higher than carbon concentration of the first layer 258B1. In some embodiments, the first layer 258B1 may have carbon concentration ranging from about 15 at % to about 30 at %, and the second layer 258B2 may have carbon concentration ranging from about 30 at % to about 70 at %. In an embodiment, the second layer 258B2 has a gradient C concentration from bottom to up. In some embodiments, the n-type source/drain extension regions 257B and the second layer 258B2 of the n-type S/D regions 258B have gradient C concentrations, and the first layer 258B1 of the n-type S/D regions 258B have a fixed C concentration. The first layer 258B1 may be doped with n-type dopants (e.g., P or As) in a range of about 3E20 to about 1E21 cm⁻³, and the second layer may be doped with p-type dopants in a range of about 5E20 to about 1E22 cm⁻³.

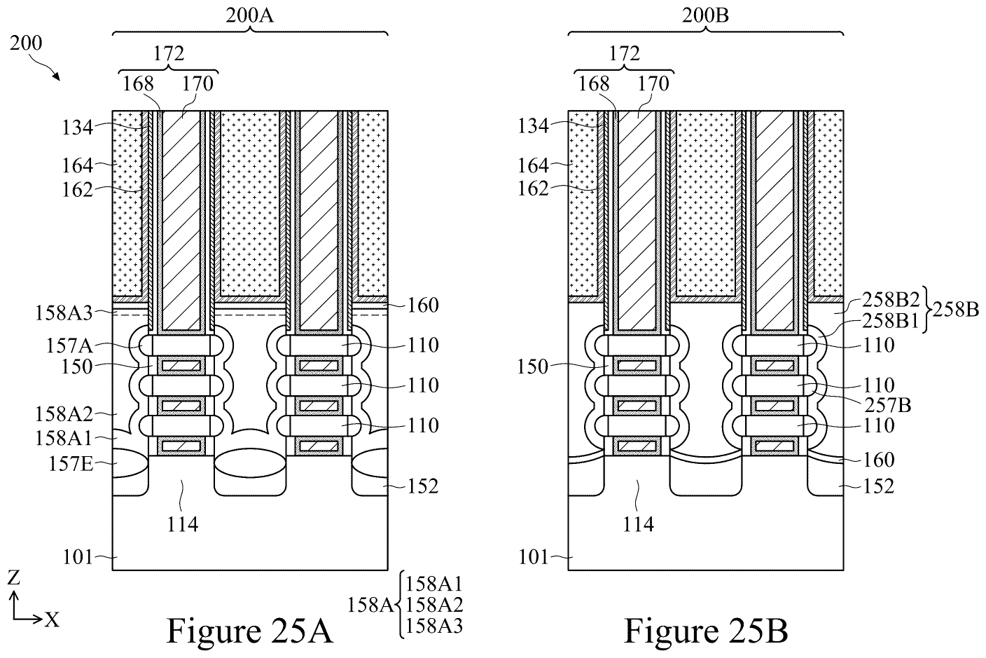

Although two layers are illustrated in the exemplary embodiments, the number of layers in the n-type S/D regions 258B is not limited, and more or fewer layers can be implemented. The n-type S/D regions 258B may generate tensile stress to the channel regions of the n-FETs in the NMOS region 200B, and the carbon material of the n-type S/D regions 258B can also be replaced with other suitable semiconductor layers that have good conductivity and can exert tensile stress to the channel regions. Next, processes similar to FIGS. 19A-21E may proceed, and a resulting exemplary structure of semiconductor device 200 is illustrated in FIGS. 25A and 25B, in accordance with some embodiments.

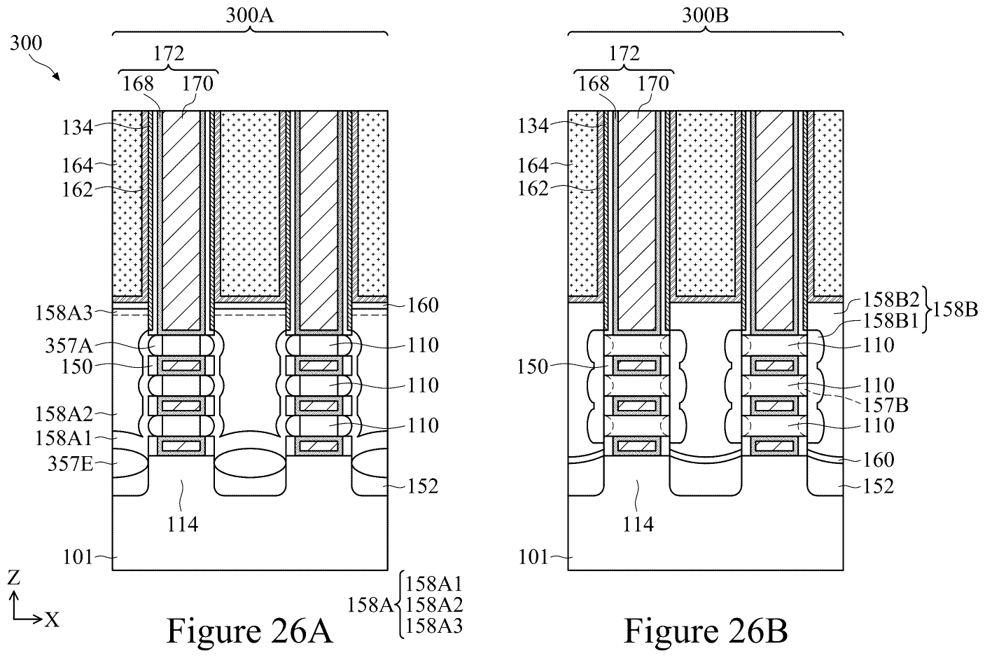

FIGS. 26A and 26B illustrate cross-sectional views of intermediate stages in manufacturing a semiconductor device 300, in accordance with some embodiments. The semiconductor device 300 is similar to the semiconductor device 100 or 200, wherein same reference numeral represents same elements. In the semiconductor device 300, p-FETs are formed in a PMOS region 300A, and n-FETs are formed in a NMOS region 300B. In some embodiments, in the semiconductor device 300, because of the abrupt doping profile junctions, the p-type source/drain extension regions 357A can be disposed more inwardly, such as overlapping the gate dielectric layer 168 and/or gate electrode 170 in the plan view in the PMOS region 300A, without significantly causing current leakage.

The materials and dopants and their concentrations of the p-type source/drain extension regions 357A may be same or similar to those of the p-type source/drain extension regions 157A. The processes of manufacturing the p-type source/drain extension regions 357A may be similar to those for manufacturing the p-type source/drain extension regions 157A, and the lateral recessing process illustrated in FIGS. 14A and 14B may last longer than those for forming the p-type source/drain extension regions 157A. Epitaxial features 357E are also formed on the buffer layer 152 when forming the p-type source/drain extension regions 357A. In other words, the epitaxial features 357E include same materials, dopants, and concentrations thereof with the p-type source/drain extension regions 357A since they are formed in same processes. In some embodiments, because the p-type source/drain extension regions 357A on opposite sides of the first nanostructures 110 becomes closer, the on-state current Iₒₙ can be increased. Although the semiconductor device 300 illustrates n-type source/drain extension regions 157B in the NMOS region 300B, it is appreciated that the n-type source/drain extension regions 257B of the semiconductor device 200 may be implemented in the semiconductor device 300.

In some embodiments, with forming p-type source/drain extension regions 357A that become closer to each other, the p-type source/drain extension regions 357A may not laterally protrude over gate spacers 134 or the inner spacers 150. As such, the lateral recess 156 (FIG. 14A) may not be fully occupied by the p-type source/drain extension regions 357A. More space can be used for growing the first layer 158A1 of p-type source/drain regions 158. The risks of forming seam in the p-type S/D regions 158A can be reduced or prevented, while forming the seam could affect the electrical conductivity of p-type S/D regions 158A and lower the performance of the semiconductor device 300. In some embodiments, the p-type S/D regions 158A are in contact with upper surfaces of the inner spacers 150 and/or the bottom surfaces of the gate spacers 134.

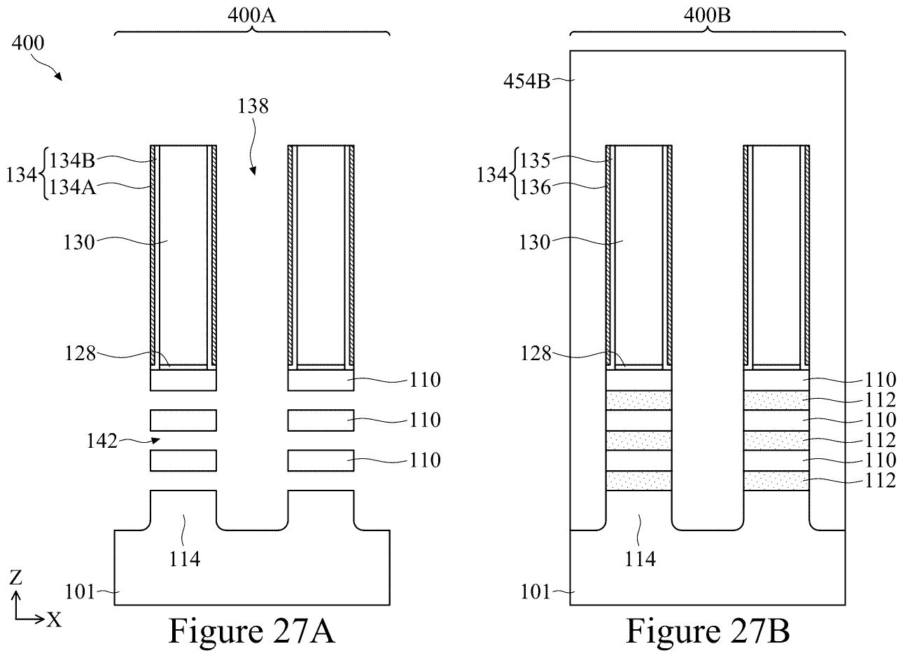

FIGS. 27A and 27B illustrate cross-sectional views of intermediate stages in manufacturing a semiconductor device 400, in accordance with some embodiments. The semiconductor device 400 is similar to the semiconductor device 100, 200, or 300, wherein same reference numeral represents same elements. In the semiconductor device 400, p-FETs are formed in a PMOS region 400A, and n-FETs are formed in a NMOS region 400B.

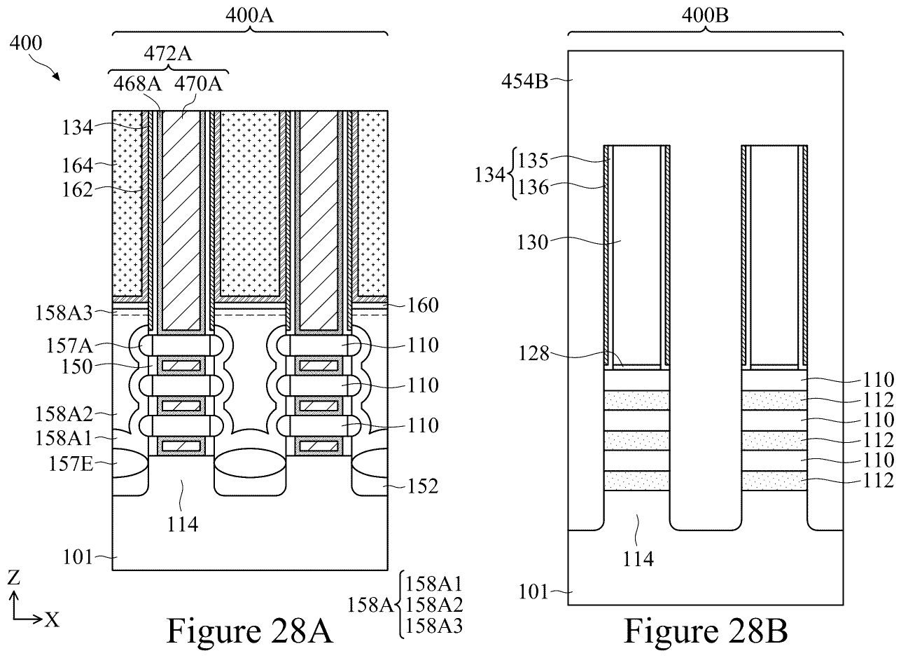

Referring to FIGS. 27A and 27B, after proceeding the processes illustrated in FIGS. 1-7B, a mask layer 454B is applied to NMOS regions 400B, and an etch process as illustrated in FIGS. 8A and 8B is performed to remove the second nanostructures 112 in the PMOS region 400A and form the second openings 142. On the other hand, the second nanostructures 112 in the NMOS region 400B may be protected by the mask layer 454B and not removed by the etch process. Thereafter, referring to FIGS. 28A and 28B, similar processes illustrated in FIGS. 9A-21E are performed but only applies to the PMOS region 400A. For example, the p-type source/drain extension regions 157A, the p-type S/D regions 158A are formed while the NMOS region 400B remains intact by being masked by the mask layer 454B during the fabrication processes for the PMOS regions 400A. In an embodiment, the gate dielectric layers 468A and the gate electrodes 470A may be or include the same materials of those of the gate dielectric layer 168 and the gate electrode 170. In some embodiments, the gate electrode 470A selects a metal material having work function suitable for P-FETs (e.g., about 4.8 eV to about 5.2 eV). The mask layer 454A may be removed by a suitable process, such as an ashing process and/or an etch process.

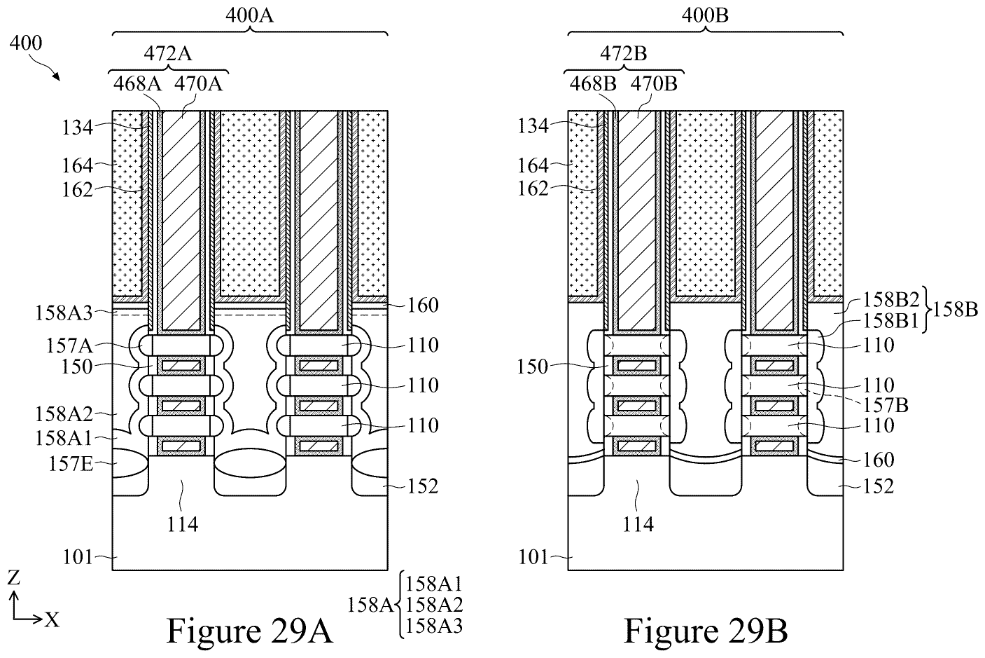

Next, in FIGS. 29A and 29B, the PMOS region 400A is masked by the mask layer (not shown), and process similar FIGS. 12A-21E are performed but only applies to the NMOS region 400B. The PMOS regions 400A remain intact by being masked by the mask layer during the fabrication processes for the NMOS regions 400B. In some embodiments, because the second nanostructures 112 are not replaced with the insulating layer 144, the etch process illustrated in 20B may use etchants suitable to remove the second nanostructures 112, such as tetramethylammonium hydroxide (TMAH), ammonium hydroxide (NH₄OH), or the like, is used. In an embodiment, the gate dielectric layers 468B and the gate electrodes 470B may be or include the same materials of those of the gate dielectric layer 168 and the gate electrode 170. In some embodiments, the gate electrode 470B selects a metal material having work function suitable for n-FETs (e.g., about 3.9 eV to about 4.4 eV). Because the gate dielectric layer 468A and the gate dielectric layer 468B are formed separately, they can individually have different materials, different thicknesses, or have individual characteristics for PMOS or NMOS purpose. Similarly, the gate electrode 470A and the gate electrode 470B are formed separately, and they can individually have different materials, different thicknesses, or have individual characteristics (e.g., work functions) for P-FETs or N-FETs purpose.

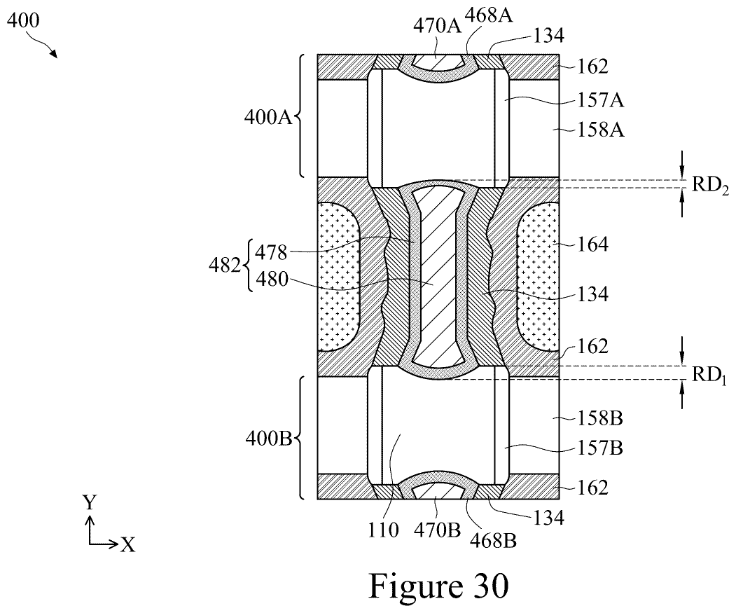

Further, referring to FIG. 30, a plan view of the semiconductor device 400 is illustrated, in accordance with some embodiments. In the manufacturing of a semiconductor device 400, because the etch selectivity between the insulating layer 144 and the first nanostructures 110 when removing the insulating layer 144 in the PMOS region 400A can be greater than the etch selectivity between the second nanostructures 112 and the first nanostructures 110 when removing the second nanostructures 112 in the NMOS regions 400B, the loss of the first nanostructures 110 in the Y-direction in the PMOS regions 400A is less than the loss of the first nanostructure 110 in the Y-direction in the NMOS region 400B. Accordingly, a gate structure deposited between PMOS region 400A and NMOS region 400B may extend into the first nanostructures 110 in the PMOS region 400A and the first nanostructures 110 in the NMOS region 400B. A first recess distance RD₁ that gate structure 482 (including gate dielectric 478 and gate electrode 480) extending into the first nanostructures 110 in the NMOS regions 400B is greater than a recess second distance RD₂ that the gate structure 482 extending into the first nanostructures 110 in the PMOS region 400A. In some embodiments, the first recess distance RD₁ is about 2.5 nm to about 5 nm, and the second recess distance RD₂ is about 0.1 nm to about 2.5 nm. The gate structure 482 may be or include a same material as the gate structure 472A in the PMOS region 400A or the gate structure 472B in the NMOS region 400B.

Embodiments of the present disclosure provide a semiconductor device and methods for manufacturing it. The method includes forming alternately stacked first and second nanostructures and replacing the second nanostructures with insulating nanostructures. The first nanostructures may have a high etch selectivity with the insulating nanostructures. Accordingly, epitaxial source/drain extension regions may be formed in openings formed by laterally recessing the first nanostructures without substantially damaging the predetermined gate structural profiles, which may be defined by the structural profiles of the insulating nanostructures. The epitaxial source/drain extension regions may include a semiconductor material (e.g., germanium) different form the semiconductor material (e.g., silicon) of the first nanostructures and thus can provide better electrical conductivity and abrupt dopant profiles junctions.

An embodiment is a semiconductor device. The semiconductor device includes: a substrate; a first nanostructure disposed over the substrate and interposed by a first epitaxial extension region and a second epitaxial extension region in a lateral direction; a second nanostructure disposed over the first nanostructure and interposed by a third epitaxial extension region and a fourth epitaxial extension region in the lateral direction, wherein the first epitaxial extension region is separated from the third epitaxial extension region, and the second epitaxial extension region is separated from the fourth epitaxial extension region, wherein each of the first epitaxial extension region, the second epitaxial extension region, the third epitaxial extension region, and the fourth epitaxial extension region includes a first semiconductor material and a second semiconductor material; a gate structure disposed over the first nanostructure and the second nanostructure, wherein the gate structure includes an upper portion interposed by a first gate spacer and a second gate spacer in the lateral direction, wherein the first epitaxial extension region and the third epitaxial extension region overlap the first gate spacer in the lateral direction, and the second epitaxial extension region and the fourth epitaxial extension region overlap the second gate spacer in the lateral direction; a first source/drain region including a first semiconductor layer connecting to the first epitaxial extension region and the third epitaxial extension region, wherein the first semiconductor layer includes the first semiconductor material and the second semiconductor material, wherein a concentration of the second semiconductor material in the first semiconductor layer is greater than a concentration of the second semiconductor material in the first epitaxial extension region; and a second source/drain region including a second semiconductor layer connecting to the second epitaxial extension region and the fourth epitaxial extension region, wherein the second semiconductor layer includes the first semiconductor material and the second semiconductor material, wherein a concentration of the second semiconductor material in the second semiconductor layer is greater than a concentration of the second semiconductor material in the second epitaxial extension region. In an embodiment, the first semiconductor material is silicon, and the second semiconductor material is germanium or carbon, wherein each of the first epitaxial extension region, the second epitaxial extension region, the third epitaxial extension region, the fourth epitaxial extension region, the first semiconductor layer, and the second semiconductor layer are doped with p-type or n-type dopants. In an embodiment, the first source/drain region further includes a third semiconductor layer laterally surrounded by the first semiconductor layer, wherein a concentration of the second semiconductor material in the third semiconductor layer is greater than the concentration of the second semiconductor material in the first semiconductor layer. In an embodiment, the first source/drain region further includes a fourth semiconductor layer disposed over the third semiconductor layer, wherein a concentration of the second semiconductor material in the fourth semiconductor layer is greater than the concentration of the second semiconductor material in the first epitaxial extension region and less than the concentration of the second semiconductor material in the third semiconductor layer. In an embodiment, the first epitaxial extension region overlaps a lower portion of the gate structure, wherein the gate structure includes a gate electrode and a gate dielectric wrapping the first nanostructure and the second nanostructure. In an embodiment, the first epitaxial extension region and the epitaxial extension region protrudes over a side surface of the first gate spacer away from the gate structure in a direction from the gate structure toward the first source/drain region. In an embodiment, the first semiconductor layer of the first source/drain region has a concave bottom surface. In an embodiment, the semiconductor device further includes a first epitaxial feature disposed between the first semiconductor layer and the substrate and a second epitaxial feature disposed between the second semiconductor layer and the substrate, wherein the first epitaxial feature includes the first semiconductor material and the second semiconductor material, wherein a concentration of the second semiconductor material in the first epitaxial feature is substantially the same as a concentration of the second semiconductor material in the first epitaxial extension region.

Another embodiment is a semiconductor device. The semiconductor device includes: a first device including: a first protrusion protruding over a substrate; a first nanostructure including a first semiconductor material and disposed over the first protrusion; a first epitaxial extension region disposed on a first sidewall of the first nanostructure; a first gate structure including a first lower portion between the first nanostructure and the first protrusion; a first insulating spacer disposed on a second sidewall of the first lower portion of the first gate structure, wherein the first epitaxial extension region overlaps the first insulating spacer; and a first source/drain region disposed adjacent to the first protrusion and the first sidewall of the first nanostructure, wherein the first source/drain region includes a first continuous semiconductor layer disposed on side surfaces of the first epitaxial extension region and the first insulating spacer, wherein the first epitaxial extension region and the first continuous semiconductor layer include a second semiconductor material, and the first continuous semiconductor layer has a higher concentration of the second semiconductor material than the first epitaxial extension region. In an embodiment, the first continuous semiconductor layer has a greater p-type dopant concentration than the first epitaxial extension region when the second semiconductor material is germanium, or the first continuous semiconductor layer has a greater n-type dopant concentration than the first epitaxial extension region when the second semiconductor material is carbon. In an embodiment, the first device further includes: a second protrusion protruding over the substrate; a second nanostructure including the first semiconductor material and disposed over the second protrusion; a second epitaxial extension region including the second semiconductor material and disposed on a third sidewall of the second nanostructure, wherein the second epitaxial extension region includes the second semiconductor material; a second gate structure including a second lower portion between the second nanostructure and the second protrusion; and a second insulating spacer disposed on a fourth sidewall of the second lower portion of the second gate structure, wherein the second epitaxial extension region laterally overlaps the second insulating spacer, wherein the first continuous semiconductor layer is in contact with the first epitaxial extension region, the second epitaxial extension region, the first insulating spacer, and the second insulating spacer. In an embodiment, the semiconductor device further includes a second device, wherein the second device includes: a third protrusion protruding over the substrate; a third nanostructure including the first semiconductor material and disposed over the third protrusion; a first extension region disposed in the third nanostructure, wherein the first extension region is substantially free of the second semiconductor material; a third gate structure including a third lower portion between the third nanostructure and the third protrusion; a third insulating spacer disposed on a fifth sidewall of the third lower portion of the third gate structure; and a second continuous semiconductor layer disposed over the third protrusion and in contact with the first extension region and the third insulating spacer. In an embodiment, the second device further includes: a fourth protrusion protruding over the substrate; a fourth nanostructure including the first semiconductor material and disposed over the fourth protrusion; a fifth nanostructure including the first semiconductor material and disposed between the fourth nanostructure and the fourth protrusion; a second extension region disposed in the fourth nanostructure, wherein the second extension region is substantially free of the second semiconductor material, wherein the first extension region and the second extension region have substantially a same dopant concentration; a third extension region disposed in the fourth nanostructure, wherein the third extension region is substantially free of the second semiconductor material; a fourth gate structure including a fourth lower portion between the fourth nanostructure and the fifth nanostructure; a fourth insulating spacer disposed on a sixth sidewall of the fourth lower portion of the fourth gate structure; and a third continuous semiconductor layer in contact with the second extension region, the third extension region, and the fourth insulating spacer, wherein the second continuous semiconductor layer is separated from the third continuous semiconductor layer. In an embodiment, the first device further includes a first epitaxial feature between the first continuous semiconductor layer and the first protrusion, and the second device further includes a second epitaxial feature between the second continuous semiconductor layer and the third protrusion, wherein a height of the second epitaxial feature is greater than a height of the first epitaxial feature. In an embodiment, the first continuous semiconductor layer has a concave bottom surface.

A further embodiment is a method for forming a semiconductor device. The method includes: forming a first semiconductor layer and a second semiconductor layer over a substrate, wherein the first semiconductor layer and the second semiconductor layer include a first semiconductor material; forming a dummy gate structure over the first semiconductor layer; forming a first gate spacer and a second gate spacer interposing the dummy gate structure in a first direction; anisotropically etching the first semiconductor layer and the second semiconductor layer using the dummy gate structure, the first gate spacer, and the second gate spacer as masks to form a first nanostructure and a second nanostructure, respectively; laterally recessing the first nanostructure and the second nanostructure; after the laterally recessing, forming a first epitaxial extension region and a second epitaxial extension region interposing the first nanostructure and a third epitaxial extension region and a fourth epitaxial extension region interposing the second nanostructure, wherein the first epitaxial extension region and third epitaxial extension region overlap the first gate spacer in a plan view, and the second epitaxial extension region and the fourth epitaxial extension region overlap the second gate spacer in the plan view, wherein the first epitaxial extension region is separated from the third epitaxial extension region, and the second epitaxial extension region is separated from the fourth epitaxial extension region, wherein each of the first epitaxial extension region, the second epitaxial extension region, the third epitaxial extension region, and the fourth epitaxial extension region includes a second semiconductor material different from the first semiconductor material; and forming a first source/drain region adjacent to the first epitaxial extension region and the third epitaxial extension region and a second source/drain region adjacent to the second epitaxial extension region and the fourth epitaxial extension region, wherein the first source/drain region includes a first continuous semiconductor layer connecting to the first epitaxial extension region and the third epitaxial extension region, and the second epitaxial extension region includes a second continuous semiconductor layer connecting to the second epitaxial extension region and the fourth epitaxial extension region, wherein each of the first continuous semiconductor layer and the second continuous semiconductor layer includes the second semiconductor material. In an embodiment, the second semiconductor material is germanium, and a germanium concentration of the first continuous semiconductor layer is greater than a germanium concentration of the first epitaxial extension region. In an embodiment, the method further includes forming a third semiconductor layer between the first semiconductor layer and the second semiconductor layer, wherein the third semiconductor layer is etched to form a third nanostructure between the first nanostructure and the second nanostructure when anisotropically etching the first semiconductor layer and the second semiconductor layer; and replacing the third nanostructure with an insulating nanostructure before laterally recessing the first nanostructure and the second nanostructure. In an embodiment, the method further includes forming a first epitaxial feature over the substrate when forming the first epitaxial extension region, the second epitaxial extension region, the third epitaxial extension region, and the fourth epitaxial extension region, wherein the first epitaxial feature includes the second semiconductor material. In an embodiment, the method further includes forming a second epitaxial feature over the substrate before forming the first epitaxial feature, wherein the second epitaxial feature includes a concave upper surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a substrate;
a first nanostructure disposed over the substrate and interposed by a first epitaxial extension region and a second epitaxial extension region in a lateral direction;
a second nanostructure disposed over the first nanostructure and interposed by a third epitaxial extension region and a fourth epitaxial extension region in the lateral direction, wherein the first epitaxial extension region is separated from the third epitaxial extension region, and the second epitaxial extension region is separated from the fourth epitaxial extension region, wherein each of the first epitaxial extension region, the second epitaxial extension region, the third epitaxial extension region, and the fourth epitaxial extension region comprises a first semiconductor material and a second semiconductor material;
a gate structure disposed over the first nanostructure and the second nanostructure, wherein the gate structure comprises an upper portion interposed by a first gate spacer and a second gate spacer in the lateral direction, wherein the first epitaxial extension region and the third epitaxial extension region overlap the first gate spacer in the lateral direction, and the second epitaxial extension region and the fourth epitaxial extension region overlap the second gate spacer in the lateral direction;
a first source/drain region comprising a first semiconductor layer connecting to the first epitaxial extension region and the third epitaxial extension region, wherein the first semiconductor layer comprises the first semiconductor material and the second semiconductor material, wherein a concentration of the second semiconductor material in the first semiconductor layer is greater than a concentration of the second semiconductor material in the first epitaxial extension region; and
a second source/drain region comprising a second semiconductor layer connecting to the second epitaxial extension region and the fourth epitaxial extension region, wherein the second semiconductor layer comprises the first semiconductor material and the second semiconductor material, wherein a concentration of the second semiconductor material in the second semiconductor layer is greater than a concentration of the second semiconductor material in the second epitaxial extension region.

2. The semiconductor device of claim 1, wherein the first semiconductor material is silicon, and the second semiconductor material is germanium or carbon, wherein each of the first epitaxial extension region, the second epitaxial extension region, the third epitaxial extension region, the fourth epitaxial extension region, the first semiconductor layer, and the second semiconductor layer are doped with p-type or n-type dopants.

3. The semiconductor device of claim 2, wherein the first source/drain region further comprises a third semiconductor layer laterally surrounded by the first semiconductor layer, wherein a concentration of the second semiconductor material in the third semiconductor layer is greater than the concentration of the second semiconductor material in the first semiconductor layer.

4. The semiconductor device of claim 3, wherein the first source/drain region further comprises a fourth semiconductor layer disposed over the third semiconductor layer, wherein a concentration of the second semiconductor material in the fourth semiconductor layer is greater than the concentration of the second semiconductor material in the first epitaxial extension region and less than the concentration of the second semiconductor material in the third semiconductor layer.

5. The semiconductor device of claim 1, wherein the first epitaxial extension region overlaps a lower portion of the gate structure, wherein the gate structure comprises a gate electrode and a gate dielectric wrapping the first nanostructure and the second nanostructure.

6. The semiconductor device of claim 1, wherein the first epitaxial extension region and the epitaxial extension region protrudes over a side surface of the first gate spacer away from the gate structure in a direction from the gate structure toward the first source/drain region.

7. The semiconductor device of claim 1, wherein the first semiconductor layer of the first source/drain region has a concave bottom surface.

8. The semiconductor device of claim 1, further comprising a first epitaxial feature disposed between the first semiconductor layer and the substrate and a second epitaxial feature disposed between the second semiconductor layer and the substrate, wherein the first epitaxial feature comprises the first semiconductor material and the second semiconductor material, wherein a concentration of the second semiconductor material in the first epitaxial feature is substantially the same as a concentration of the second semiconductor material in the first epitaxial extension region.

9. A semiconductor device comprising:
a first device comprising:
a first protrusion protruding over a substrate;
a first nanostructure comprising a first semiconductor material and disposed over the first protrusion;
a first epitaxial extension region disposed on a first sidewall of the first nanostructure;
a first gate structure comprising a first lower portion between the first nanostructure and the first protrusion;
a first insulating spacer disposed on a second sidewall of the first lower portion of the first gate structure, wherein the first epitaxial extension region overlaps the first insulating spacer; and
a first source/drain region disposed adjacent to the first protrusion and the first sidewall of the first nanostructure, wherein the first source/drain region comprises a first continuous semiconductor layer disposed on side surfaces of the first epitaxial extension region and the first insulating spacer, wherein the first epitaxial extension region and the first continuous semiconductor layer comprise a second semiconductor material, and the first continuous semiconductor layer has a higher concentration of the second semiconductor material than the first epitaxial extension region.

10. The semiconductor device of claim 9, wherein the first continuous semiconductor layer has a greater p-type dopant concentration than the first epitaxial extension region when the second semiconductor material is germanium, or the first continuous semiconductor layer has a greater n-type dopant concentration than the first epitaxial extension region when the second semiconductor material is carbon.

11. The semiconductor device of claim 9, wherein the first device further comprises:
a second protrusion protruding over the substrate;
a second nanostructure comprising the first semiconductor material and disposed over the second protrusion;
a second epitaxial extension region comprising the second semiconductor material and disposed on a third sidewall of the second nanostructure, wherein the second epitaxial extension region comprises the second semiconductor material;
a second gate structure comprising a second lower portion between the second nanostructure and the second protrusion; and
a second insulating spacer disposed on a fourth sidewall of the second lower portion of the second gate structure, wherein the second epitaxial extension region laterally overlaps the second insulating spacer, wherein the first continuous semiconductor layer is in contact with the first epitaxial extension region, the second epitaxial extension region, the first insulating spacer, and the second insulating spacer.

12. The semiconductor device of claim 11, further comprising a second device, wherein the second device comprises:
a third protrusion protruding over the substrate;
a third nanostructure comprising the first semiconductor material and disposed over the third protrusion;
a first extension region disposed in the third nanostructure, wherein the first extension region is substantially free of the second semiconductor material;
a third gate structure comprising a third lower portion between the third nanostructure and the third protrusion;
a third insulating spacer disposed on a fifth sidewall of the third lower portion of the third gate structure; and
a second continuous semiconductor layer disposed over the third protrusion and in contact with the first extension region and the third insulating spacer.

13. The semiconductor device of claim 12, wherein the second device further comprises:
a fourth protrusion protruding over the substrate;
a fourth nanostructure comprising the first semiconductor material and disposed over the fourth protrusion;
a fifth nanostructure comprising the first semiconductor material and disposed between the fourth nanostructure and the fourth protrusion;
a second extension region disposed in the fourth nanostructure, wherein the second extension region is substantially free of the second semiconductor material, wherein the first extension region and the second extension region have substantially a same dopant concentration;
a third extension region disposed in the fourth nanostructure, wherein the third extension region is substantially free of the second semiconductor material;
a fourth gate structure comprising a fourth lower portion between the fourth nanostructure and the fifth nanostructure;
a fourth insulating spacer disposed on a sixth sidewall of the fourth lower portion of the fourth gate structure; and
a third continuous semiconductor layer in contact with the second extension region, the third extension region, and the fourth insulating spacer, wherein the second continuous semiconductor layer is separated from the third continuous semiconductor layer.

14. The semiconductor device of claim 12, wherein the first device further comprises a first epitaxial feature between the first continuous semiconductor layer and the first protrusion, and the second device further comprises a second epitaxial feature between the second continuous semiconductor layer and the third protrusion, wherein a height of the second epitaxial feature is greater than a height of the first epitaxial feature.

15. The semiconductor device of claim 9, wherein the first continuous semiconductor layer has a concave bottom surface.

16. A method for forming a semiconductor device, the method comprising:
forming a first semiconductor layer and a second semiconductor layer over a substrate, wherein the first semiconductor layer and the second semiconductor layer comprise a first semiconductor material;
forming a dummy gate structure over the first semiconductor layer;
forming a first gate spacer and a second gate spacer interposing the dummy gate structure in a first direction;
anisotropically etching the first semiconductor layer and the second semiconductor layer using the dummy gate structure, the first gate spacer, and the second gate spacer as masks to form a first nanostructure and a second nanostructure, respectively;
laterally recessing the first nanostructure and the second nanostructure;
after the laterally recessing, forming a first epitaxial extension region and a second epitaxial extension region interposing the first nanostructure and a third epitaxial extension region and a fourth epitaxial extension region interposing the second nanostructure, wherein the first epitaxial extension region and third epitaxial extension region overlap the first gate spacer in a plan view, and the second epitaxial extension region and the fourth epitaxial extension region overlap the second gate spacer in the plan view, wherein the first epitaxial extension region is separated from the third epitaxial extension region, and the second epitaxial extension region is separated from the fourth epitaxial extension region, wherein each of the first epitaxial extension region, the second epitaxial extension region, the third epitaxial extension region, and the fourth epitaxial extension region comprises a second semiconductor material different from the first semiconductor material; and
forming a first source/drain region adjacent to the first epitaxial extension region and the third epitaxial extension region and a second source/drain region adjacent to the second epitaxial extension region and the fourth epitaxial extension region, wherein the first source/drain region comprises a first continuous semiconductor layer connecting to the first epitaxial extension region and the third epitaxial extension region, and the second epitaxial extension region comprises a second continuous semiconductor layer connecting to the second epitaxial extension region and the fourth epitaxial extension region, wherein each of the first continuous semiconductor layer and the second continuous semiconductor layer comprises the second semiconductor material.

17. The method of claim 16, wherein the second semiconductor material is germanium, and a germanium concentration of the first continuous semiconductor layer is greater than a germanium concentration of the first epitaxial extension region.

18. The method of claim 16, further comprising:
forming a third semiconductor layer between the first semiconductor layer and the second semiconductor layer, wherein the third semiconductor layer is etched to form a third nanostructure between the first nanostructure and the second nanostructure when anisotropically etching the first semiconductor layer and the second semiconductor layer; and
replacing the third nanostructure with an insulating nanostructure before laterally recessing the first nanostructure and the second nanostructure.

19. The method of claim 16, further comprising forming a first epitaxial feature over the substrate when forming the first epitaxial extension region, the second epitaxial extension region, the third epitaxial extension region, and the fourth epitaxial extension region, wherein the first epitaxial feature comprises the second semiconductor material.

20. The method of claim 19, further comprising forming a second epitaxial feature over the substrate before forming the first epitaxial feature, wherein the second epitaxial feature comprises a concave upper surface.
